(19) United States
(12) Patent Application Publication
(10) Pub. No.: US 2024/0203610 A1
(43) Pub. Date: Jun. 20, 2024

(54) LIQUID METAL COMPOSITIONS FOR USE AS PLASMA FACING COMPONENTS

(71) Applicant: Michael T. Kotschenruether, Austin, TX (US)

(72) Inventor: Michael T. Kotschenruether, Austin, TX (US)

(73) Assignee: Fusion Energy Associates LLC, Austin, TX (US)

(21) Appl. No.: 18/514,783

(22) Filed: Nov. 20, 2023

Related U.S. Application Data
(60) Provisional application No. 63/426,733, filed on Nov. 19, 2022.

(51) Int. Cl. G21B 1/11

(52) U.S. Cl. CPC G21B 1/11

(57) ABSTRACT

A surface exposed to a plasma or energetic particles (“plasma-exposed surface”) in a device to confine a plasma, including a liquid composition wherein metallic elements dominate by atomic fraction and wherein elements with Z<26 are not primarily lithium by atomic fraction.

### CROSS-REFERENCE TO RELATED APPLICATIONS

This application claims priority to U.S. provisional application Ser. No. 63/426,733 filed on Nov. 19, 2022, which is incorporated herein by reference in its entirety.

### FIELD OF INVENTION

This invention generally relates to devices that contain plasma. It can apply to magnetically confined plasmas, such as those that are used in the field of fusion energy. More specifically, it relates to materials that face the plasma which are in the liquid state.

### BACKGROUND OF THE INVENTION

It is widely acknowledged that Plasma Facing Components (PFCs) are a critical issue for a Fusion Power Plant (FPP) for magnetically confined plasmas. The unique environment of a PFC is even more challenging than the already difficult one for structural materials in the blanket of a fusion reactor. The PFC is exposed to similar neutron fluxes as the blanket, but the thermal stresses are higher (sometimes incomparably so), and there are additional unique hurdles. The severe environment of a fusion PFC is not found in any other technological circumstance:

A) High transient heat fluxes (originating through multiple diverse pathways), with an intensity that will melt or evaporate the surface of any material, could potentially strike many regions in off-normal conditions. Such transients are inherently difficult to predict accurately; the diversity of pathways and complexity of the phenomena (disruptions, ELMs, hot particle instabilities, complex control system faults of multiple types, etc.) make it realistically impossible to accurately know ahead of time, for any particular design, the probability of these events.

B) A need for long service lifetimes of the order of a full power year and hopefully much more.

C) Large fluences of very hard neutrons

D) Very high continuous heat fluxes that can exceed 10-20 MW/m² (in the divertor)

E) Inevitable erosion of surfaces in contact with plasma caused by processes unique to plasmas

F) This eroded material is redeposited elsewhere in the device, with potentially serious consequences for a fusion reactor

G) Excessive high-Z material from the PFC must not get into the core plasma, even though this can happen by disparate routes: sputtering, evaporation, and flaking of redeposited material. Such material in the core plasma would quench the fusion reaction.

Accordingly, Liquid Metals (LM) are often discussed as a PFC option with several intrinsic advantages over solid options. Items A and B above are perhaps the most often cited reasons to consider them, since LM PFCs can be replenished in situ.

Of course, the system designs of fusion devices aspire to reduce the probability of transients to the extent foreseeable. But experience with a very wide range of complex technological systems demonstrates that the probability of undesirable events, in long term operation, cannot be accurately predicted ahead of time. Since LMs have a considerably higher intrinsic resilience to the factors above, they are a logical design option to pursue, even though they have their own special challenges. This disclosure relates to LM PFCs with unique advantages over those that are known in the art. But before turning to these in more detail, the following points should be realized:
1) Given the present substantial uncertainties at the plasma edge of magnetically confined plasmas, arising from both technological and physics unknowns, future experience might prove that the intrinsic advantages of LM PFCs make them indispensable rather than optional for many device designs.
2) Since the entire research effort of magnetic confinement fusion (of the order of $100 billion cumulative expenditure world-wide and rising) is contingent on viable PFCs that must operate reliably in unprecedented conditions despite a high level of present-day uncertainty, developing LM PFCs could be imperative to the future plans for fusion devices by both companies and governments. Many of these plan to construct fusion reactors or test reactors in the next several years.
3) LM PFCs such as those disclosed here would have uniquely strong advantages for all the issues A-F above.

There is one final general issue which is generally underappreciated. Since PFCs are the interface between the plasma and the material device, the operational regime of the plasma is a crucial factor in the workability of a PFC. Hence, the plasma operating mode near the edge is often modified to accommodate the PFC. Edge plasma conditions have a major impact upon the core plasma conditions where fusion occurs, and such accommodations can easily lead to significant degradation of the performance of the core plasma. In other words, although a PFC technology may “work” for some plasma conditions, global aspects of the reactor can be degraded, such as: a) increases in reactor cost due to degraded confinement, b) increased disruption probability due to operation near density limits and high radiation fraction, c) increased recirculating power fraction due to poor current drive efficiency, and d) other global degradation depending upon the particular fusion design concept.

The conventional PFC solutions demand the adjustment (downwards) of the core plasma to be compatible with the PFC technology. One would wish, however, to do exactly the opposite: the PFC technology should be so chosen as to be compatible with the best core conditions that are allowed by physics.

A PFC solution that allows a significant improvement in the global performance of the device would have enormous leverage and value. It would allow a reactor vender to make a superior reactor. The value of the PFC would extend far beyond the value of a just providing a viable PFC solution (although that would also have considerable value, of course).

### SUMMARY OF THE INVENTION

Liquid metals have been considered as Plasma-Facing Components (PFCs) for plasma devices such as those used to contain nuclear fusion. Various configurations are considered for such devices, but all have the plasma coming into contact with a material wall at some position. Such devices may have a particular magnetic field configuration, and examples include, but are not limited to, tokamaks, Spherical Tokamaks (STs), stellarators, toroidal pinches, Reversed Field Pinches (RFPs), spheromaks, magnetic mirrors, Z pinches, Field Reversed Configurations and other configurations. Such PFCs can also be considered in plasma devices without a confining magnetic field. Here we disclose LMs for use as PFCs that have advantages over those that are already known in the art.

As is known within the existing art, one reason that liquids have advantages over solids (such as Tungsten) for PFCs is that they can have the important benefit of being “self-healing”, that is, they can easily be replenished in situ when there is high plasma-caused erosion. Such high erosion can result from transient plasma events or from continuous exposure to the plasma.

One specific location where LMs are attractive is at the divertor target, which is where most of the heat that is exhausted from the core plasma is deposited. This area can have very high erosion. But they could also be beneficial as PFCs at many locations.

We now describe in more detail why LM PFCs could be tremendously advantageous for a high-performance Fusion Power Plant (FPP). An attractive tokamak or ST Fusion Power Plant [Menard 2022] requires high current drive efficiency (low core density, high core temperature) simultaneously with confinement much better than a nominal H-mode values (H˜1.5-1.8). Here H is the factor by which the actual confinement time must exceed the standard scaling law for the H-mode confinement time. Even higher H than this would be desirable, since it would enable a reduction of the size and cost of a demonstration Fusion Power Plant.

Therefore, it is highly noteworthy that the experiment closest to a reactor, JET-ILW, only achieves even nominal H-mode confinement (H=1) when the plasma divertor temperature T_{e div} is high [Lomanowski 2022]. See FIG. 1A, based upon experimental data from JET-ILW presented in that reference. A T_{e div}˜30 eV is much higher than is conventionally considered for a fusion reactor such as an FPP, since at this value of plasma temperature, divertor erosion for a solid target would be unacceptable for a reactor for multiple reasons. These include short PFC lifetime due to rapid erosion, and excessive dust generation [Stangeby 2011]. LM PFCs allow the divertor target to be continuously replenished, so that such erosion is acceptable. Liquids also do not create dust, hence LM PFCs are likely necessary to operate with such a T_{e div}.

The trend visible in the JET-ILW data in FIG. 1A implies that confinement could be improved considerably by operation with T_{e div} significantly higher than 30 eV.

As is known in the art, high T_{e div} arises together with low density at the divertor target ne div. And low ne div arises if the density upstream of the divertor at the separatrix, nₛₑₚ, is low. See FIG. 2 for a description of the geometry.

Another example of relevant data is that in the International Tokamak Physics Activity global H-mode database [Verdoolaege 2021]. It shows a clear trend of improved confinement with reduced nₛₑₚ. See FIG. 1B. For the major tokamak ASDEX-U, enhancements up to twice the H-mode are possible at low SOL density nₛₑₚ, if the PFC materials of the plasma are also of low Z.

Such enhancements above H-mode confinement are highly desirable, since it implies a considerably smaller and less expensive device can achieve fusion gain.

Recent gyrokinetic analysis has elucidated the physical mechanisms causing edge transport, which is how the edge affects the confinement. From this understanding, it is likely that increasing the plasma temperature at the Tₛₑₚ, or reducing nₛₑₚ, are likely a rather universal route to increase core confinement, because all the operative instabilities that degrade confinement can be strongly improved by going along this route. The dominant mechanisms causing energy losses are Electron Temperature Gradient (ETG) modes, Micro-Tearing Modes (MTM), neoclassical transport, Kinetic Ballooning Modes (KBM), and Ion Temperature Gradient/Trapped Electron Modes (ITG/TEM) [a review can be found in Kotschenreuther 2019, a peer reviewed scientific paper authored by the inventor of this patent which has already been referenced over 100 times in the scientific literature.] All of these instabilities cause much less transport as one progresses to a regime with lower separatrix density and higher separatrix temperature: these conditions lead to low or reversed magnetic shear, and a high ratio of density gradient to temperature gradient in the edge plasma. As recent extensive analysis shows [Kotschenreuther 2023], ITG/TEM and ETG are stabilized by these conditions. KBM are stabilized from higher edge bootstrap current that reduces magnetic shear. And MTM and neoclassical transport are reduced by lower collisionality since collisions are the strongest destabilization mechanism.

Experiments do indeed bear out this trend. The experimental results from JET-ILW and ASDEX-U are clear examples of this. Another example is the EP H-modes on NSTX. Although these are significantly different from JET-ILW and ASDEX-U in detail, qualitatively, these same types of instabilities are operative, and enhanced confinement was found experimentally with low nₛₑₚ and progressing further into a regime of low recycling [Bataglia 2020]. The experiment TFTR was even more different than either of these, but confinement was observed to improve as recycling was reduced, which reduced the edge plasma density and increased the edge plasma temperature [Strachan 1994].

Some mix of the instabilities mentioned above are operative in all magnetic configurations. Hence, the ability to reach higher confinement performance with higher separatrix T and lower separatrix density likely pertains to magnetic configurations other than tokamaks, including stellarators and toroidal pinches, Reversed Field Pinches, Field Reversed Configurations, spheromaks, Z pinches, and other configurations.

So, to recapitulate, it is very likely that there is a continuum of confinement improvements as T_{div} is increased and n_{div} is decreased, and this occurs as recycling is reduced, for a wide variety of magnetically confined plasma devices.

Now, let us see how these conditions lead to the need for LM PFCs.

The simple solution of choosing a solid PFC for such conditions is widely acknowledged to be impractical for a fusion power plant. The erosion rate would lead to unrealistically short replacement times for a solid PFC (as short as a day or less). Also, operation at high T_{e div} with solid PFCs would likely lead to very high levels of dust, which ultimately terminates operation (as observed in the Large Helical Device experiment [Shoji 2015]). Such dust can also lead to severe safety hazards in case of an accidental loss of vacuum, due to dust explosions when mixed with air, and release of radioactive dust to the atmosphere. High dust accumulation would not be permitted by regulatory authorities.

Accumulated erosion and dust can become unacceptable problems in plasmas that operate for a long time. One example of this situation is for producing fusion energy in a power plant.

Low values of nₛₑₚ, just like high T_{e div}, would also lead to unacceptable erosion for a solid PFC in a fusion reactor setting [Stangeby 2011].

In order to operate at higher T_{e div} and low nₛₑₚ, LM PFCs are needed since liquids allow rapid replenishment of the eroding PFC surface in situ and they avoid dust.

But in addition to the need for LMs, there is also a need for the surface of the LM to be low Z, as we now describe.

The ASDEX-U results only find very high confinement at low nₛₑₚ when the PFC is low Z, but not when it is high Z. And in JET-ILW, which has high Z PFCs in the divertor, experimental attempts to have sustained operation with T_{e div} much higher than 30 eV lead to intolerable levels of high Z impurities in the core, resulting in loss of confinement. Thus, PFCs where a low Z element is at the surface of the PFC are likely crucial in order to have maximum confinement when nₛₑₚ is low and T_{e div} is high.

Problematic high Z impurities arise by sputtering [Huber 2019]. It is important to realize that the problem of high Z impurities is not cured by choosing a high Z material with a low vapor pressure. While low vapor pressure is necessary, it is not sufficient. Tungsten has a negligibly low vapor pressure, and yet by sputtering, it leads to unacceptable core plasma contamination in JET-ILW unless plasma operation is severely constrained to low T_{div} and high n_{div}—the opposite of the conditions desired for optimal confinement. And tungsten PFCs prevented ASDEX-U from attaining high confinement with low nₛₑₚ.

Conditions of high T_{e div} or low nₛₑₚ lead to strong sputtering for all Z materials. However, the damage these impurities do to the core plasma depends strongly upon Z. It is well-known that the main way that high Z materials damage the core plasma is by causing energy loss by radiation. To see how this damage varies with the Z of the impurity, FIG. 3 gives the radiation per atom, for representative fusion plasma core temperatures, for various impurities. (This is taken from International Atomic Energy Atomic Molecular Data Services page, see the reference IAEA-FLYCHK.) As we see, tungsten gives the highest radiation loss. Sn and In, which are a conventional choice for LMs for LM PFCs currently in the art, are only slightly better than tungsten. Gallium, another conventional LM for LM PFCs in the art, is about one order of magnitude better than tungsten, but is by no means the metal with lowest radiation. Metals with lower Z, that might possibly be on the surface of a LM PFC, would be considerably lower yet, as seen in FIG. 3. Lithium (Z=3) and Beryllium (Z=4), not shown, would be the lowest.

There is an additional reason why low Z PFCs are important under the conditions of high T_{e div} or low nₛₑₚ. For sufficiently high T_{div}, eventually a catastrophic form of sputtering called “avalanche” self-sputtering occurs. This is perhaps the most dangerous kind of sputtering, whereby a sputtered impurity from the PFC causes exponentially more impurities. Low Z PFCs are needed to avoid this, and the ones disclosed here do so.

The well-known mechanism of avalanche self-sputtering is the following. An atom is sputtered off the PFC, and is then ionized in the SOL. It is then accelerated back to the PFC. The particle will impact the PFC with an energy that is roughly proportional to T_{div}, in fact, it's likely about 3-4 times T_{div} after falling through the well-known sheath at the PFC surface [Stangeby 2011]. This high energy impact of the impurity will result in the sputtering of yet more impurities, and for obvious reasons this is called self-sputtering. If the average sputtering yield per event is above one, this process can exponentiate. This is called an “avalanche”. This must be absolutely avoided, as it would result in huge amounts of impurity injected into the plasma.

Avalanches become an issue when the self-sputtering yield approaches and exceeds one. In practice, there are various losses in the SOL so that self-sputter yields somewhat above one are tolerable, but the margin above one is nonetheless finite. As one can see in FIG. 4, even neglecting increases in sputtering from temperature dependent sputtering, the PFC material responsible for sputtering is a primary determinant of the maximum T_{div} that is attainable.

The summary of all the considerations above is that low Z materials on the surface have crucial advantages.

The novel LMs disclosed here segregate low Z metals such as Li, Be, Mg, Al, Si and Ca to the surface. The sputtered impurities resulting from this would cause much less core radiation than for conventional LMs known in the art such as Sn, In and Ga. By having low Z elements facing the plasma, operation with much lower nₛₑₚ and higher T_{div} than 30 eV becomes possible without unacceptable core radiation, and without the danger of avalanche self-sputtering.

Impurities can also arise by evaporation, not just sputtering. Importantly, the conventional LMs with low vapor pressure have rather high Z. For Sn, In and Ga, the sputtering from such alloys is also high Z.

So, an attractive PFC to allow higher confinement should have sputtering from low Z elements. But the vapor pressure should also be low to avoid impurities from evaporation, which favors high Z LMs. How do we combine the advantages for both low Z and high Z?

Uniquely for a liquid, this is possible even if the bulk material is primarily composed of high Z elements with low vapor pressure: a minority low Z element can segregate to the surface of a high Z liquid under appropriate conditions that we describe below. The vapor pressure of the alloy will in fact still be low (since it is thermodynamically determined by bulk properties, as is very well demonstrated) but the sputtering will be low Z, with all the advantages of low Z mentioned above.

It is well known that sputtering is primarily determined by the atomic monolayer at the surface. So, by controlling the material that is segregated to the surface, one controls the sputtered material. This general principle is already known in the general area of sputtering. It has been demonstrated experimentally for several LM alloys outside the context of PFCs [Deoli 2014, Hubbard 1989]. The specific LM alloys examined in those experiments are not desirable for PFCs because the segregated element is high Z. But the experiments demonstrate the general principle that segregation controls sputtering for LMs.

In fact, the experimental measurements indicate that the effect can be quite dramatic. For the alloy GaBi, even if the Bi is only 0.2% in the bulk allow, it nonetheless totally dominates the sputtering: about 80% of the sputtered material was measured to be Bi [Deoli 2014]. For this particular alloy example, the segregation can be understood as an example of classical Gibbs segregation. This attributes the large segregation of GaBi to extremely large differences in surface tension between Ga and Bi. In fact, theoretical estimates (by the author) of the degree of segregation expected due to surface tension, at the temperature of the experimental measurement above, is in agreement with the observation that the surface should consist almost entirely of Bi. Hence, the sputtering should as well.

The example of GaBi in the paragraph above is a particularly extreme and dramatic example. The requisite large difference in surface tension does not occur for desirable alloys for LM PFCs. Also, they operate at much higher temperature, which greatly reduces the segregation effect from surface tension.

In general, segregation occurs because there is an energetic advantage for a particular element to concentrate on the surface rather than the bulk. One mechanism for this is based upon surface tension. But there are other mechanisms. The energetic strength of the chemical segregation mechanism described in this disclosure is far stronger than the surface tension mechanism. In fact, at the operating temperature of the LM PFCs, it is energetically stronger than even the surface tension effect in GaBi at low temperature. Hence, the chemical segregation mechanism described here can result in desirable LM PFC alloys, with highly advantageous segregation, even when the desired segregant is a low percentage of the alloy. And it does this for conditions where surface tension effects, already known in the LM PFC art [Kessel 2019] are entirely inadequate to achieve such desirable results.

For the case of LM PFCs, such segregation has been observed experimentally for the alloy SnLi [Kessel 2019, Bastasz 2004]. And when used as an LM PFC in a magnetically confined plasma, the alloy SnLi was found to result in impurities that were strongly dominated by Li [Tabares 2017]. But the mechanism behind it has not been understood before now. After the author understood the mechanism underlying this, it becomes possible to use the same mechanism for other alloys, and hence to devise very advantageous alloys for LM PFCs that were not realized previously in the art.

In summary, it is known that by segregating a low Z element to the surface, the problem of high Z impurities in the core plasma can be greatly reduced or eliminated. The challenge we address in this disclosure is to describe a means by which such segregation can be accomplished for a wider class of alloys than SnLi, which have advantageous properties in comparison to the SnLi alloys considered before now.

In addition to improving sputtering, the disclosed alloys have additional advantages for an LM PFC. Before describing these, we briefly summarize the present status of LM PFCs, to illuminate their problems.

We start by briefly discussing the most obvious requirement for an LM divertor: the liquid must stay in place, away from the core plasma. The Capillary Pore System (CPS) is a viable solution for this, based upon experience in many experiments. The CPS is a kind of metal “sponge” to hold the liquid in place by the action of wetting. Wetting of LM on a CPS has been shown to keep the LM in place in plasma experiments. For example, LM PFCs on a CPS have been tested at in plasma experiments, including several tokamaks and a stellarator. They have withstood high heat fluxes of up to 10-20 MW/m² without apparent ill effects on the plasma or the CPS [Dejarnac 2020, Mazzitelli 2019, Tabares 2017]. In a recent experiment with the LM tin, plasma contamination was a problematic issue [Scholte 2023]. This is one example that shows that finding improved LMs for use as PFCs is important.

The EU fusion DEMO program is pursuing an option for a liquid tin PFC, confined on a CPS, for use in the divertor of a DEMO fusion reactor. Since this endeavor is from a large team of scientists and engineers in the large EU fusion program, it shows that the concept is deemed possible even under fusion reactor conditions.

The CPS has another crucial benefit: the parallel heat flux in a divertor is so high that, unless the PFC is maintained at a low angle of incidence with the magnetic field, ANY material will VERY quickly vaporize. To keep the angle shallow, the LM surface must be quite smooth, and a solid substrate can insure this. For example, the LM on the divertor surface cannot have waves or ripples. Such perturbations would lead to very high local incident heat flux on sections of the ripple, and unacceptable vaporization. It is hard to ensure that such perturbations don't arise for an unconstrained liquid surface. A solid CPS “stabilizes” the liquid surface to maintain the requisite smoothness. (A concept from the University of Illinois called LIMITs uses very shallow metal trenches and concomitant wetting forces, acting is a manner similar to a CPS. [Ruzic 2011])

The EU DEMO is pursuing this LM PFC divertor concept because the resilience to transients appears promising: a major advantage of the concept relative to solid divertor PFCs, which was mentioned above. [Rindt 2021].

The EU DEMO design is based upon tin. Tin has a high Z (Z=50, not highly different from tungsten with Z=74). It is not surprising that it has qualitatively similar problems to those found with tungsten in JET-ILW. Divertor simulations of the EU divertor with Sn LM PFC found that to avoid unacceptable high Z impurities in the plasma, the Sn LM divertor must operate with high density and strong radiation from impurity seeding—in other words, a low T_{div} [Nallo 2022]. This leads to roughly the same drawbacks as tungsten—a need for plasma operation that is not optimal for core confinement, as we described above.

The ITER water cooling technology is being adapted to this LM PFC: because of this, the steady state heat flux is limited to the range ˜20 MW/m² [Roccella 2020]. Heat is exhausted at quite low temperature into the water, so it has little worth for conversion to electricity. This is another disadvantage of this LM PFC.

Other concepts for LM PFCs are being considered. Lithium has been considered as an evaporative PFC material [Goldston 2017]. This should have excellent transient resistance. However, this concept is the opposite of a low recycling divertor; it is a kind of kind of “ultra-high recycling” divertor: it delivers even more atoms into the SOL per plasma atom impact than a standard high recycling divertor regime. This likely leads to quite low T_{e div} and high nₛₑₚ with the same consequences described above: a lower confinement than is possible with high T_{e div} and low nₛₑₚ.

Lithium has been considered as a means of attaining low recycling regimes [Zakharov 2019, Majeski 2010] which have high T_{e div} and low nₛₑₚ, and thus good confinement. For this application, lithium requires a low surface operating temperature to avoid excessive evaporation or temperature dependent sputtering, which is very challenging since the heat fluxes in the divertor are extremely high.

Several liquid metals are well known in the prior art as candidates for PFCs. The following have been highly investigated in the previous art for this purpose: lithium (Li), tin (Sn), gallium (Ga), Indium (In), and the alloy tin-lithium (SnLi).

All the metals and alloys known in the prior art suffer serious drawbacks:
1) Lithium has a relatively high vapor pressure, and the evaporated metal would create impurities in the plasma, which would unacceptably dilute it if the evaporation rate was too high. It is generally acknowledged that the impurity level would become unacceptable for a modest surface temperature (variously estimated as above roughly 400-450° C. [Castro 2021], or above 300-380° C. [Kessel 2019]). It is extremely hard to maintain such temperatures for a divertor PFC, because of the extremely high heat flux incident on the surface—which can be 10 MW/m², or even several times this. In most lithium PFC concepts, this leads to a requirement for rapid flow of the LM to avoid overheating. This is very challenging in a strong magnetic field such as that in a fusion reactor, which strongly damps flow by MagnetoHydroDynamic (MHD) effects. After several decades of effort, attaining such rapid flows over the large regions needed are still far from being accomplished.
2) The other conventional LMs (Sn, Ga, SnLi and In) have much lower vapor pressure, and so can operate at much higher temperature. However, Sn and Ga have a much higher Z than lithium, so per atom, they are far more damaging to plasma performance if they become a plasma impurity. This can arise by sputtering as well as evaporation. And it does not appear likely that the conventional alloys compositions of Sn and Li SnLi (where Li has an atomic fraction of 20-30%) have enough of an improved temperature operating window to overcome the challenges of the enormous heat fluxes.
3) If the divertor plasma temperature T_{e div} is high, as occurs in a low recycling divertor which improves the performance of the core plasma (TSOL˜a 100 eV or more), self-sputtering of high Z impurities becomes an “avalanche” which is unacceptable.
4) Perhaps most seriously of all, the conventional materials (Li, Sn, Ga, SnLi) have been measured to suffer extremely strong temperature dependent sputtering, that is, for LM surface temperatures TLM above ˜400-500° C., the sputtering increases extremely rapidly [Allain 2001, Conn 2002, Coventry 2004, Allain 2007]. And just as with lithium, it is very hard to maintain a low enough TLM to avoid this phenomenon because of the high incident heat flux for all the conventional LMs.

We mention other deleterious ramifications of the need for low temperature with existing materials, due to the problems above.

1) LM “wetting” of a substrate often decreases substantially as temperature decreases. To see how crucial wetting is, consider the following. We consider typical parameters for a scenario where the SOL is in a regime for very high plasma core performance. If poor wetting causes the solid substrate to be exposed only ˜1% of the time, the resulting plasma erosion would force it to be replaced unacceptably quickly.

Unacceptable LM surface temperatures are most easily avoided by having the LM be very thin. However, basic physics of liquid surfaces implies that the thinner a liquid layer is, the more energetically favorable it is for it to “bead up”, thereby leaving bare spots (by basic physics of surface tension). This would result in the unacceptable plasma erosion mentioned above. If wetting is weak due to low temperature, it would be a severe challenge to maintain a thin film reliably over a long time.

2) Heat exhausted from lithium would very likely not be at the high temperatures considered for high conversion efficiency, because of the surface temperature limits. This is a “waste” of that thermal energy, degrading overall economics of a power plant.

3) In the case of Li, a fast-flowing Li needed to keep the temperature low implies that very large volumes of lithium must flow, and this must be continuously recycled to extract tritium. This is a significant issue for the cost and complexity of the balance of plant.

A summary is: temperature limits of LMs lead to a host of serious issues and problems. Materials that can operate at higher temperature could greatly alleviate them.

Before proceeding, we mention two other important issues for an LM PFC, where improvements would be welcome.

1) Wetting. Wetting is essential for a PFC based upon CPS, to keep the LM in place with complete coverage and to provide good thermal contact with the substrate for heat removal from the LM. Hence, improvements in wetting are highly beneficial for LM PFCs.

2) Corrosion. The conventional LMs are compatible with substrates of refractory metal such as tungsten (W) or molybdenum (Mo). However, over long-term operation, oxide build-up might be a problem for the substrate surface for some LMs, e.g., Sn, Ga, and In. Surface oxides generally degrade wetting by an LM, often quite strongly. And often, corrosion leads to material loss of the substrate over time. Hence, it would be advantageous, for long term operation, to have LMs that reduce substrate corrosion and oxide formation.

Here, novel Liquid Metal (LM) alloys are disclosed to overcome the drawbacks above. We will give a brief description of the alloys, their advantages, and the reason why they have these advantages.

Before the analysis of the author of this application, it was not realized in the art that the following properties hold, and that novel alloy compositions can utilize these properties to make greatly improved LM PFCs possible. Neither this analysis, nor the novel alloys, have been publicly disclosed up to now.

(By alloy, we mean that the liquid consists of more than one element, and metallic elements cumulatively make up the preponderance of the atoms in the liquid. Silicon will be considered a metallic element or metal in this disclosure, and Boron will be considered a non-metallic element or non-metal.)

1) Low Z metallic elements can be induced to segregate to the surface by surface active agents. Those low Z metals thereby dominate the sputtered atoms that contaminate the plasma. As outlined above, low Z elements are far less detrimental than high Z. Potential low Z metallic elements in an alloy include Li, Be, Mg, Al, Si and Ca.

2) Low Z metallic elements other than Li may not suffer high levels of temperature dependent sputtering, and hence, they can be very advantageous additions to an LM PFC. Specifically, elements whose melting point is significantly higher than Li will be able to operate at higher temperature than Li, without suffering high levels of temperature dependent sputtering, which is a major benefit for an LM PFC. These low Z metallic elements include, but are not limited to, Be, Mg, Al, Si and Ca.

3) The presence of small amounts of non-metals in the bulk volume of the LM act as surface active agents. They will segregate to the surface of the LM, and have a far higher concentration there, thereby improving sputtering in several ways. These non-metallic elements include O, N, F, P, S, Cl and in some cases H or B. When they are present on the surface in significant amounts, they will draw the low Z metallic elements mentioned above to the surface, so that sputtering is dominated by those low Z elements.

They will also form compounds with metallic elements, which will be segregated to the surface and hence dominate sputtering. These compounds include, but are not limited to, oxides, nitrides, fluorides, phosphides, sulfides, chlorides, hydrides, or borides. These compounds nearly always have lower sputtering coefficients and much less temperature dependent sputtering than pure metals of elements such as Ga, Sn, In, Al, and Cu, as well as the low Z metallic elements in 1 above, for example, Li.

4) The properties above relate to improving the sputtering characteristics of an LM, and this occurs because they modify the surface of the LM. However, properties of the volume LM are also important to have a practical LM PFC. Vapor pressure is determined essentially by the thermodynamic properties of the bulk. Other important bulk properties include the melting point and thermal conductivity. Hence, the properties 1, 2 and 3 above can be used in alloys where the volume properties are desirable, but where the sputtering and other surface properties can be improved substantially. The other surface properties include wetting. Corrosion is another property that can be improved.

These characteristics enable LMs with these advantages:
1) The elements that are segregated to the surface have lower atomic number Z than Ga, Sn and In, so they have a less damaging effect upon the core if they are ejected into the plasma
2) They can operate when exposed to a plasma with higher plasma temperature T_{e div}, and this would result in higher confinement of the core plasma, and other performance improvements of the core plasma.
3) The vapor pressure of the LM is low, and the thermal conductivity may also be improved.
4) Properties 1-3 imply that they can operate with higher LM material surface temperature TLM
5) Property 4) plus an improved thermal conductivity allows them to withstand a higher heat flux from the plasma.
6) Some of the LMs have improved wetting to solid substrates
7) Some of the LMs have improved corrosion properties with respect to solid substrates
8) An additional desirable property of some alloys is the following. One problem with all PFCs is that exposure to excessive heat flux for sufficient time can damage solid components, i.e., the solid substrate upon which the PFC resides will be overheated. In such an event, for some of the alloys disclosed here, the high surface temperature of the LM will lead low Z elements being evaporated or sputtered into the SOL. In some cases, this can be sufficient to lead to radiation in the SOL that disperses heat away from the PFC, and so lowers the heat flux. Thus, the alloys are also self-protecting, that is, they avoid damage to the solid substrate of the LM in the event of excessive heat flux by causing radiation in the SOL to reduce said heat flux. This is accomplished by the evaporation or sputtering of low Z elements in an alloy when it is overheated. We will refer to this property as radiative self-protection.

The only alloy that is conventionally considered for PFCs is Tin-Lithium, SnLi. The fraction of Li has been in the range of roughly 20-30%. This material has been experimentally measured to have a desirable segregation of the Li to the surface in some cases [Bastasz 2004], but analysis is inconsistent. For the first time, the author of this patent has understood the mechanism for the Li segregation. A correct application of the operative mechanism makes it possible to devise many different novel LM alloys which will have substantially improved capabilities, and such novel alloys are disclosed here. In addition to segregating low Z material to the surface, which improves sputtering, the same alloy can have improved vapor pressure, wetting, corrosion properties and radiative self-protection.

One important application for these alloys is as components of a divertor system, where the plasma heat is exhausted onto the LM. For example, patent applications entitled “Increasing energy gain in magnetically confined plasmas by increasing the edge temperature: the Super-XT divertor” by Inventor Michael T. Kotschenreuther, filed on Jan. 28, 2023, discloses a divertor where the heat is deposited on one surface which can be a liquid metal, and low recycling is achieved in other locations, and this is made possible by the combination of magnetic and physical geometry and materials disclosed in that provisional patent. The alloys disclosed here would be attractive for use as a PFC in such a Super-XT divertor. The disclosed alloys would also be attractive as PFCs at the divertor target in other LM divertors. They would also be attractive for PFC in locations other than the divertor target. For yet another example, they would also be attractive PFCs for applications in the patent application entitled “Edge Current Drive in Magnetic Fusion Devices” by Inventor Michael T. Kotschenreuther, filed on Oct. 12, 2023. They could also be useful in other applications as well.

### BRIEF DESCRIPTION OF THE FIGURES

FIG. 1A (PRIOR ART) shows data from the JET tokamak, showing the confinement enhancement factor H over H mode verses the divertor plasma temperature T_{e div}. (From B. Lomanowski and the JET Team, Nucl. Fusion 62 (2022) 066030) As we see, the confinement improves as the divertor temperature T_{e div} is increased. Even nominal H-mode confinement requires divertor temperatures in excess of T_{e div}˜ 30 eV, which would lead to unacceptable erosion in a fusion reactor.

FIG. 1B (PRIOR ART) shows Data from another major tokamak, ASDEX-U, from the International Tokamak Physics Activity database (G. Verdoolaege 2021 Nucl. Fusion 61 076006). The confinement enhancement factor H shows a clear trend of improvement with decreasing SOL density, here shown as the ratio of the plasma density on the separatrix nₛₑₚ to the core density n_{core}. Strong confinement improvements are only found for low Z PFCs.

Note that nₛₑₚ and T_{e div} are related, and lower nₛₑₚ leads to higher T_{e div}. The low values of nₛₑₚ/n_{core}

FIG. 2 Shows an exemplary geometry of a plasma exposed surface. The plasma has a core region 201 and a surface that separates the core region from the edge region 202. Heat and particles leak out of the core and travel along magnetic field lines in the region between 203 and 230 to a divertor region 204 next to a target PFC 205. In some embodiments there are multiple divertor regions. This example shows a second divertor region 240 and an associated PFC 250.

FIG. 3 shows energy losses by radiation per atom of impurity in the core for representative conditions in a fusion reactor. Higher Z impurities have much higher energy loss per atom. (For representative fusion plasma density 10¹⁴ cm⁻³, units are ergs/sec/atom, from International Atomic Energy Atomic Molecular Data Services page https://www-amdis.iaea.org/FLYCHK/)

FIG. 4 shows Approximate self-sputtering yield verses particle energy for classical sputtering, that is, not considering temperature dependent sputtering. These are taken from various data in the literature. Self-sputtering yields significantly above one lead to catastrophic “avalanche” self-sputtering. The impact energy of an impurity striking the plate is roughly proportional to the SOL temperature. One can estimate E_{impact}=3-4 T_{e div}. As can be seen, lower Z materials allow considerably higher T_{e div} while avoiding avalanches. Conventional LMs such as Ga and In might be limited to T_{e div} of only ˜100 eV. Note that Sn would be somewhat similar to In. Beryllium is somewhat above Li, but well below Si. So, if low Z elements could be segregated to the surface, considerably higher values of T_{e div} should be attainable while avoiding self-sputtering avalanches. Since T_{e div} and nₛₑₚ are related, the ability to attain higher T_{e div} also means that lower nₛₑₚ is attainable. These lead to higher confinement in view of FIG. 1A and FIG. 1B. Thus, lower Z PFCs can allow higher confinement to be attained.

FIGS. 5A, 5B, 5C, 5D, 5E, 5F and 5G show experimentally measured sputtering yields verses temperature. Data for four LMs are shown: lithium (Li), tin (Sn), gallium (Ga) and an alloy of tin and lithium SnLi. For all four liquid metals, sputtering rapidly and strongly increases starting at a temperature of ˜400-500 C. Specifically, the sputtering yield (atoms ejected per atom impinging) increases and accelerates with increasing T.

FIGS. 5a and 5b (PRIOR ART) show sputtering from Li, for various projectiles [Allain 2007]. They all show temperature dependent sputtering. FIG. 5c shows that the sputtering follows an Arhennius relation. This is a temperature dependence upon T proportional to exp(−E/KT), for some E, and k is Boltzmann's constant. This type of relation is followed in an extremely diverse variety of physical-chemical phenomena, including evaporation, solubility, chemical reaction rates, etc. This behavior is visible as a line when plotting on a log scale vs 1/T, as in FIG. 5c. FIG. 5d shows that temperature dependent sputtering arises in actual plasma exposure [Doerner 2001], as expected, and the rate of emission of target atoms can often exceed evaporation. FIG. 5e shows that temperature dependent sputtering also occurs in the alloy SnLi [Allain 2007], and the onset temperature is only slightly higher than for pure Li. FIG. 5f shows that such sputtering appears in compounds of lithium with carbon as well [Scotti 2014] and is similar to the case of pure lithium or projections for lithium hydride. FIG. 5g and FIG. 5h show that temperature dependent sputtering arises for Ga [Conn 2002] and Sn [Coventry 2004], respectively.

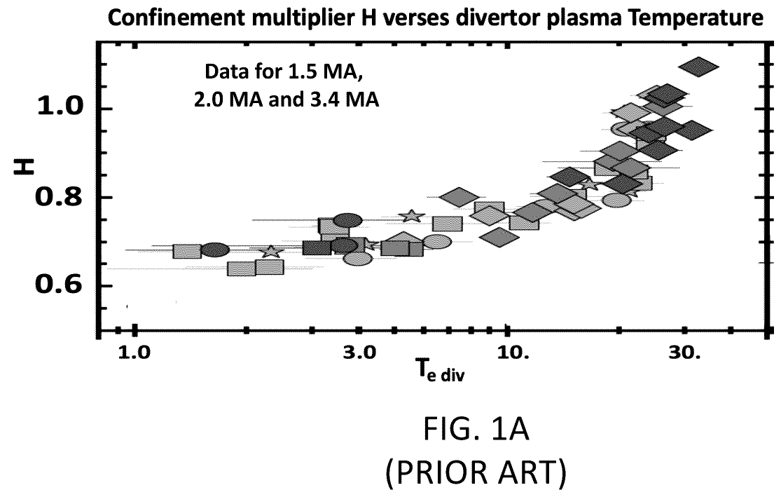

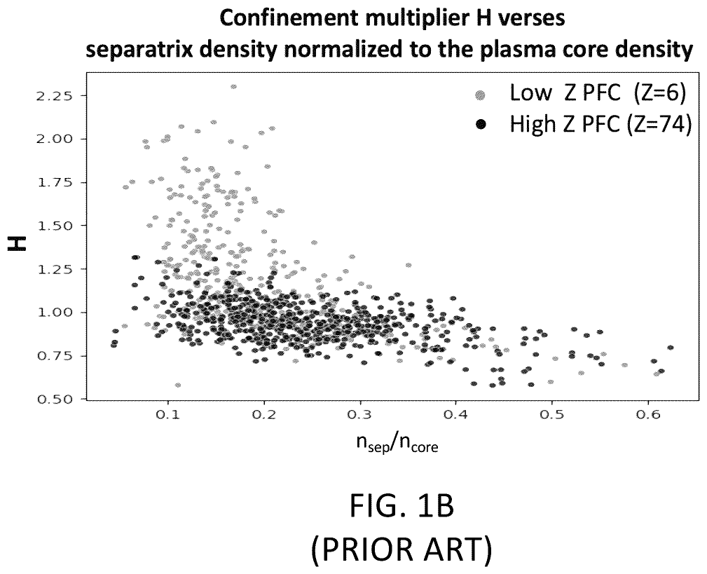

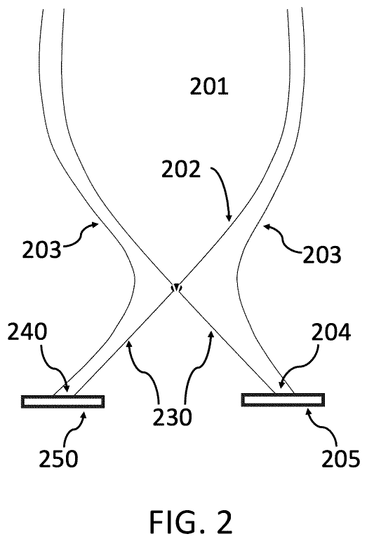

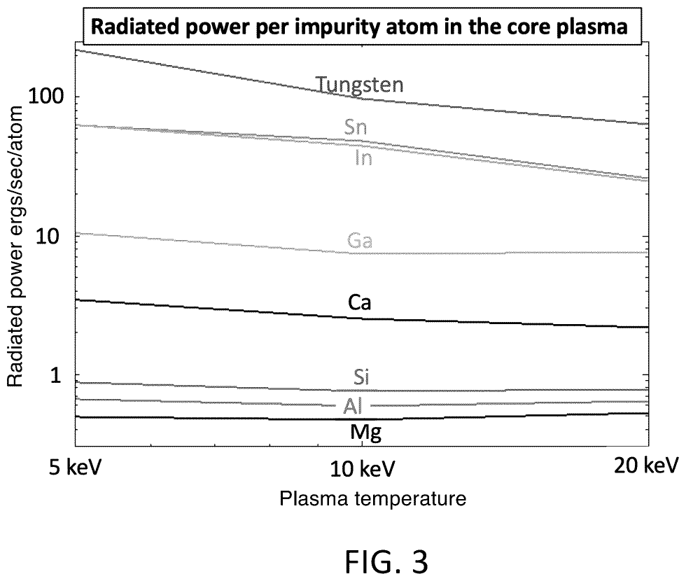

### DETAILED DESCRIPTION

The fusion community has previously considered five different LM materials: Li, Sn, Ga, SnLi and In. Implementing LM divertors with these metals, especially devising designs that are workable in fusion reactor conditions, has proven to be very challenging. As is often the case in technological development, challenges can be greatly eased once “better” materials are available. Here, we disclose novel alloys that have major advantages over the five conventional LMs.

Recall the desirable properties that are required:
1) Low vapor pressure at high temperature
2) A low Z material segregated to the surface facing the plasma, by the phenomenon of surface segregation
3) Avoiding strong sputtering at high surface temperature of the LM, TLM
4) Desirable bulk properties such as high thermal conductivity and a melting point that is low enough to allow LM PFC to be used together with other structural materials in the system. (For example, the CPS material, the substrate and pipes to transport the material.) If the melting point is too high, there is an unacceptable risk the LM would solidify during an operational fluctuation, leading to serious damage.
5) Ability to accept a high heat flux
6) Low corrosion with suitable substrates
7) Good wetting of a substrate

The property 5) follows from 1-4 combined.

The property of melting point mentioned in 4) is necessary for the LM PFC material to be practical as part of a total system in a plasma device. It has led the LM PFC community to consider low melting point metals such as Ga, Sn, and In. However, other LMs have other desirable properties which might make them useful additions if the LM operates at high enough temperature to avoid solidification.

For example, Copper Cu and Aluminum Al have high thermal conductivity, even in the molten state. They both also have fairly low vapor pressure. This can aid with attaining property 5, even though their melting point is high. Copper and aluminum are often used in the solid state in applications where its thermal conductivity is beneficial, allowing a higher heat flux to be accepted in the application. It is rare for this property to be a reason for its inclusion in molten alloys. The usefulness of Cu or Al as part of a molten alloy has never been considered for LM PFC, but it is another possible addition to an LM PFC. Other elements might also be considered as well.

However, Cu and Al have high melting points, especially Cu. Hence Cu can only be used as part of an LM PFC that always operates at high temperature. And Cu is fairly high Z. And this, in turn, requires that the surface interactions with the plasma are acceptable at high temperature. In other words, properties 2) and 3) must apply to any alloy with significant Cu component, as well as property 1).

Let us see how to formulate alloys with the desirable properties that are required.

The new alloys must have low vapor pressure at relatively high temperatures. This property is, relatively speaking, one of the easiest to engineer. The equilibrium vapor pressure of molten alloys is a subject that is well understood and predictable. It is well known that even if one element of an alloy has relatively high vapor pressure, the alloy can act like a type of chemical compound which binds it to the liquid state more strongly than for the pure element alone. One instance of this phenomenon is the alloy SnLi, where the Li vapor pressure is reduced by three orders of magnitude by virtue of being in the alloy. This effect can be engineered far more generally by appropriate tailoring of alloy members. This has never been done before with the goal of designing an improved alloy as a PFC, and this is one aspect of the innovative alloys here.

In this regard, it is known that if an alloy has only a small mole fraction x of an element with a relatively high vapor pressure, the partial pressure of that element is reduced by x if there are no other chemical effects (Raoult's law). The chemical effects in the paragraph above are known to reduce the vapor pressure to values lower than Raoult's law (by affecting the so-called activity). By a combination of low x and reduced activity, an alloy that consists of a high fraction of a low vapor pressure member (examples of which include, but are not limited to, some proportions of Ga, Sn, In, Cu and Al), together with a of small fraction of a low Z element that has relatively high vapor pressure (examples of which include Li, Magnesium Mg, Calcium Ca), can still have low vapor pressure. And in addition, if the low Z element itself has low vapor pressure (examples of which include, but are not limited to, Beryllium Be, Aluminum Al, Silicon Si), then the alloy will definitely have low vapor pressure.

So, examples of new alloys for LM PFCs include, but are not limited to, alloys with some proportion of Ga, Sn, In, Cu and Al as the majority component, together with some proportion of Li, Be, Mg, Al, Si or Ca as a minority component. Such alloys have never been considered for LM PFCs (with the exception of SnLi. Also GaLi and InLi have been mentioned in passing [Kessel 2019] in this context, but never considered seriously).

As we will see below, there are other elements that are important additions to an alloy, in addition to the elements just mentioned, in order to facilitate properties 2 and 3. As we will see, these elements include, but are not limited to oxygen O, nitrogen N, fluorine F, carbon C, sulfur S, phosphorus P, Chlorine Cl, and possibly hydrogen H and its isotopes, and possibly Boron B, in order to facilitate the segregation of the low Z minority component to the surface. Note that the requisite concentration of these elements can be extremely low (in some cases perhaps parts per million).

Properties 2 and 3 are more challenging to arrange than property 1) Reiterating these: 2) the alloy presents a relatively low Z element (or elements) to the plasma at the surface of the LM, by the phenomenon of surface segregation, and 3) this segregated material is chosen to try to avoid a major problem that has been measured in the conventional LMs, namely, that there is a very strong increase in sputtering as the material temperature increases past a threshold.

Designing desirable new alloys that satisfy conditions 2) and 3) above requires three things:
a) Means must be found to segregate the low Z element to the surface of an alloy
b) low Z element that avoids temperature dependent sputtering must be determined.
c) The low Z elements cannot unacceptably degrade other properties such as melting point or vapor pressure. The latter properties also depend on the concentration of the low Z element.

So, in all cases, the key is a strong segregation mechanism that allows a low concentration of an element in the bulk to be segregated to the surface.

The novel alloys we disclose are based upon novel means of satisfying a), b) and c) together.

Regarding, specifically, consideration a): we will see below that this is facilitated by the addition of minority components with low Z such as N, O, F, C, P, S, Cl and possibly H and B. This can cause a strong segregation of the elements Li, Be, Mg, Al, Si, and Ca.

Regarding, specifically, consideration b): we will see below that low Z metallic elements that are likely to accomplish this are Beryllium, Magnesium, Aluminum, Silicon, and Calcium. Lithium in the alloy SnLi has already been experimentally shown to have substantial temperature dependent sputtering.

Regarding c), because such chemical means are a strong segregation mechanism, even a low Z element with rather small concentration in the bulk can be segregated to the surface. This allows otherwise desirable properties to be maintained due to the low concentration of the low Z element.

We begin with consideration a) above: how to engineer segregation of the low Z elements.

Surface segregation in molten alloys is reasonably well understood within metallurgy and physical chemistry. There are multiple possible mechanisms that can lead to it. The simplest mechanism is classic “Gibbs segregation” arising from surface tension. This mechanism is already known within the fusion community of LM PFCs [Kessel 2019]. While this mechanism can be used to develop new alloys, unfortunately, analysis by the present author shows that it is too weak to segregate most of the desirable elements that are likely to avoid temperature dependent sputtering, while maintaining the desirable properties of the bulk alloy such as low melting temperature. Specifically, because the segregation is not extremely strong, a large fraction of the desired segregant must also be present in the bulk alloy, and this raises the melting point of the bulk alloy to a degree that makes the alloy less attractive.

For the first time, the author has identified another segregation mechanism that can be used to devise attractive LM PFCs.

The operation of a mechanism other than surface tension is indicated by the fact that SnLi has shown a strong segregation of Li, and sputtering, in numerous contexts ([Bastasz 2004] [Allain 2007 pg 205434-4], [Tabares 2017]), but various published analysis cannot explain how. Surface tension engendered segregation is far too small [Krasin 2019, and this author's own independent analysis] to account for the magnitude of the segregation effect observed in several experiments. Published ab-initio molecular dynamics simulations to—investigate segregation in SnLi for PFCs also predict weak surface segregation: the alloy Li₃₀Sn₇₀ has a surface concentration of only ˜40% Li [Del Rio 2019]. This is quite similar to the surface tension analysis: quite weak segregation.

All the analysis above agrees that the predicted segregation of Li in SnLi is almost two orders of magnitude too weak to explain the sputtering measurements of [Allain 2007] and [Tabares 2017]. Some strong mechanism must be operating that is not accounted for in those analysis.

The author has recognized and understood (for the first time to his knowledge) the actual mechanism responsible for strong segregation of Li in SnLi found in sputtering experiments and surface measurements. The same mechanism can be used to engineer the segregation effect in other novel alloys for LM PFCs. The mechanism is based upon understanding developed in a totally different area technological area.

Within metallurgy, segregation is investigated primarily because of its effect upon surface tension. Surface tension is known to be determined primarily by the monolayer of atoms at the surface. Surface tension is a very important property to understand in many common industrial processes, especially casting of metals into molds. And chemical processes that lead to segregation were understood in metallurgy to improve this technology, by improving understanding of surface tension. So, by developing an understanding of surface tension for casting, the field of metallurgy has also developed an understanding of surface segregation.

Sputtering is of critical importance to LM PFCs, and crucially, sputtering also depends upon the atomic monolayer at the surface. So, the same principles of segregation that were developed to understand surface tension in metallurgy can be applied to LM PFC to improve the totally unrelated property of sputtering in this completely different technological area of materials exposed to a high energy plasma.

Evidently the area of casting technology is totally unrelated to the area of LM PFC technology. And similarly, sputtering is, of course, totally irrelevant to casting. But the understanding of segregation that was developed in metallurgy for casting can be applied to the totally different technological area of LM PFCs, to develop materials with greatly improved sputtering. The field of LM PFCs has never considered chemical segregation to develop novel PFC materials with improved sputtering. So, the results of applying understanding that arose in casting technology to the totally different area of LM PFCs can result in materials with novel and advantageous properties in that area.

As found in metallurgy, it is nearly universal in molten metals that tiny amounts of oxygen (often parts per million) in the bulk material can lead to nearly complete coverage of the surface by oxygen [Gheribi 2019]. This can happen by exposure to a gas with an extraordinarily low amount of oxygen. One representative quote from the scientific literature is “it turns out that, even under ultra-high vacuum conditions, corresponding to oxygen partial pressures of about 10-12 bar, the oxygen content of the liquid phase can be largely sufficient to saturate the liquid surface” [PASSERONE 1990]. For Sn, oxygen pressures of 10-10 bar strongly affect the surface tension (Fiori 2005), and hence, the surface monolayers. For Gallium, pressures of order 10-10 bar lead to oxygen rich layers several atoms thick that cover the surface [Regan 1997].

Such low pressures of oxygen could certainly be arranged in a divertor for an LM PFC. Alternatively, very low concentrations of oxygen could also be added to the LM prior to exposure to the plasma. This could be done by adding compounds of O, or by exposure to the gas. The requisite concentration in the metal could be extremely low.

Other non-metallic elements are known to have a similar effect. This same phenomenon arises from other surface-active elements in addition to oxygen, and which occur in metallurgical contexts related to casting; these include nitrogen N, fluorine F, carbon C, phosphorus P, sulfur S, and under some circumstances possibly hydrogen H, and potentially B. The elements we have listed have low Z, so they are suitable for the surface of a PFC. These surface-active elements can be introduced into the LM alloy in various ways, including, but not limited to, exposure to a gas or plasma containing them, or as liquid or solid elements, or compounds that contain the element. Such additions can be performed either prior to exposure of the LM to the plasma, or during exposure to the plasma, or any combination of these two.

Let us return to the case of SnLi, which is one example of the principles above. Measurements of its surface composition find that high lithium segregation is accompanied by considerable oxygen present on the surface [Bastasz 2004] (O is roughly 30-35% of the surface when the Li surface segregation is strong.)

In the case of SnLi, such surface oxygen will bind much more strongly to Li than to Sn. This preferentially draws Li to the surface to the oxygen, and the basic energetics of this effect can easily be far stronger than surface tension. This chemical process is the primary agent of segregation in SnLi. The author is the first to realize this, to his knowledge.

This phenomenon is observed in alloys outside fusion and is chemically understood: a surface-active agent such as oxygen draws other elements to the surface that strongly bind to it. A simple treatment can be found in [Joud 1995], for example, outside of the context of LM PFCs. The specific metal alloy considered in that work, PbSn, is of no interest for LM PFCs, because the segregant has high Z. But the chemical principle is the same for low Z elements in alloys to improve LM PFCs.

This mechanism, which is understood within metallurgy, is doubtless the reason why the observed Li segregation in SnLi is far stronger than can be understood from surface tension arguments. This has been a puzzle in the area of LM PFCs before now.

The basic chemistry of this effect should apply to low Z surface active agents other than oxygen, such as N, F, C, P, S, Cl, and in some circumstances possibly H (and its isotopes), possibly B, and other elements. These elements can segregate to the surface and also have strong preferential binding to low Z metallic segregants (including, but not limited to, Li, Be, Mg, Al, Si and Ca) compared to the bulk members of the alloy (including, but not limited to, Ga, Sn, In, and Cu). Hence, the low Z metallic segregant will be concentrated on the surface of the alloy.

The surface-active agents listed above all have low Z (Z<18). In an LM PFC with these elements, they will be sputtered into the plasma. Because they have low Z, they will not cause severe damage to the core plasma.

Having understood the mechanism of chemical segregation, it becomes possible to arrange advantageous segregation in various alloys. Appropriate surface active agents such as those listed above can be introduced into the LM PFC. This can then bind to a low Z metallic alloy member which is desired to be segregated to the surface, drawing them to the surface. Fortunately, these low Z metallic elements chemically almost always bind more strongly to the low Z surface active agents than to the high Z bulk alloy members such as Ga, Sn, In, Cu, or others.

This produces the desired segregation of the low Z metallic elements in LM PFCs.

Hydrogen, and its isotopes, is not considered to be a surface-active agent for most alloy elements in metallurgy. However, when an alloy contains a constituent that strongly binds to hydrogen, it may have the effect of drawing it to the surface. Within the field of metallurgy, this effect can be inferred for some alloys containing strontium Sr, due to the effect of hydrogen exposure on the surface tension of the alloy [Anson 1999]. For LM PFCs, Sr is not a desirable surface segregant, since it is high Z. However, the low Z element Ca, which is immediately above Sr in the periodic table, binds almost as strongly to H as does Sr. LM PFCs are continuously exposed to hydrogen isotopes from the plasma, so this could be a route to introduce D or T as surface active agents for desirable surface segregant elements such as Ca. Lithium also binds to H, though less strongly than Sr. This effect might well encourage segregation of Li to a surface in the context of a PFC where the plasma contains hydrogen or its isotopes.

In summary, the introduction of surface-active elements such as N, F, C, P, S, CI, H and its isotopes, and B, leads to their segregation to the surface. For a multi-component alloy consisting of majority constituents such as Ga, Sn, In, Cu, and possibly others, these surface-active elements lead to the segregation of minority low Z metallic elements including, but not limited to, Li, Be, Mg, Al, Si, and Ca.

This should also lead to a cure for the problem of temperature-dependent sputtering, to which we now turn.

Specifically, we now consider how to choose a segregant that avoids temperature dependent sputtering.

Temperature dependent sputtering is perhaps the most challenging phenomenon to deal with, since the experimental observations (on Li, Ga, Sn and SnLi) do not have a strong theoretical understanding. But by carefully examining the patterns in the extant data, including the data for sputtering of other molten alloys, one can determine materials and temperature ranges that are very likely to avoid this pernicious phenomenon.

The author is the first person to notice these patterns in the data, which lead to a solution to the problem of temperature dependent sputtering. The novel alloys disclosed here are based upon these patterns, and hence are also give a novel means to avoid it.

More details are given below, but a summary is:
1) Temperature dependent sputtering for all measured LMs only occurs in an element above its melting point
2) If that element is only slightly above its melting point, in liquid form, strong temperature dependent sputtering will not occur
3) So, it is not enough that an element to be liquid to manifest strong temperature dependent sputtering, it must be somewhat above the melting point as well
4) If said element does not manifest strong sputtering in liquid form slightly above its melting point, it surely should not manifest such sputtering below the melting point, if it was somehow still in liquid form
5) Said element can indeed still be in liquid form if it is a member of a suitable alloy whose melting point is lower than that element. Many alloys are liquid at a temperature below the melting point of some of their constituents.
6) Said element can be segregated to the surface by some means, including the chemical means described above.
7) This should prevent temperature dependent sputtering, since the surface is covered by atoms of an element below its melting point, and this is below the threshold of temperature dependent sputtering for that element.

There is another strategy to avoid temperature dependent sputtering. Large temperature dependent sputtering does not happen to solids generally [Allain 2005], and specifically, in compounds such as oxides, nitrides, or other compounds, at least, not until the temperature is in the vicinity of the melting point of the solid. For such compounds, this temperature is usually very high. As we described above, such compounds of metallic elements and non-metallic elements usually segregate to the surface of an alloy. Hence, even without introducing a new metallic element in an alloy, one should be able to eliminate temperature dependent sputtering as follows by this second strategy:
1) Choose an element that is strongly segregated to the surface of an alloy or liquid element. We will call this element a surface-active agent. Examples include elements mentioned in the section above, such as O, N, F, C, P, S, Cl, and possibly H or B, and possibly others.
2) This element usually tends to form compounds with a metallic element of the liquid, or with multiple metallic members of the liquid if it is an alloy. For example, that compound could be an oxide, nitride, fluoride, carbide, phosphide, sulfide, chloride, hydride, or possibly others.
3) The compounds in 2), when they are not on the surface of an LM, are solids at the operating temperature of the alloy
4) The resulting LM with the surface-active agent should prevent temperature dependent sputtering.

In each of the cases above, the surface-active ingredient must be replenished as sputtering erodes it away. This will require a means for such replenishment. As mentioned above, there are multiple possible ways to do this: they can be introduced into the LM alloy by exposure to the surface-active element as a gas or plasma, or as elements in the liquid or solid form, or as compounds that contain the element, or by other means. When hydrogen can be a surface-active agent, then this could be replenished by the incident plasma particle flux.

Let us now examine the patterns in the data in detail.

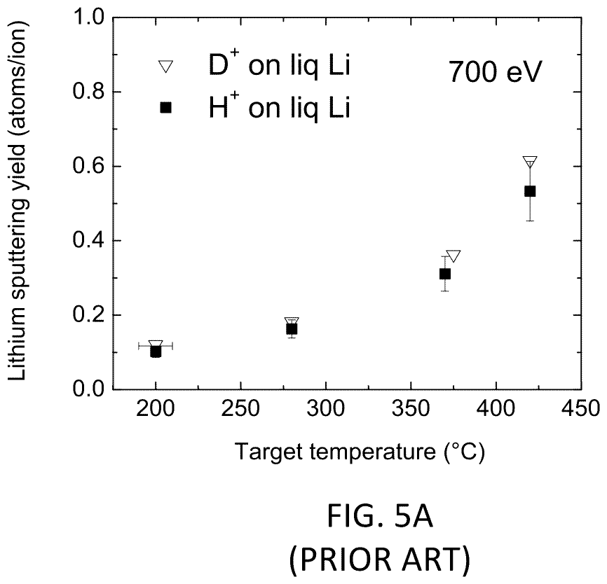

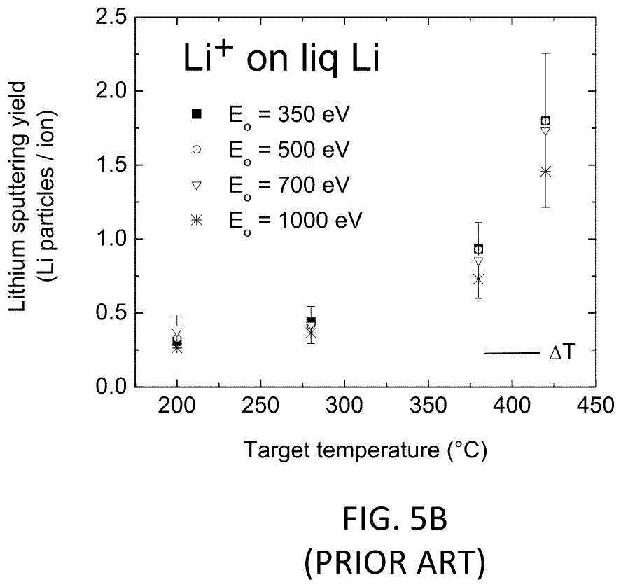

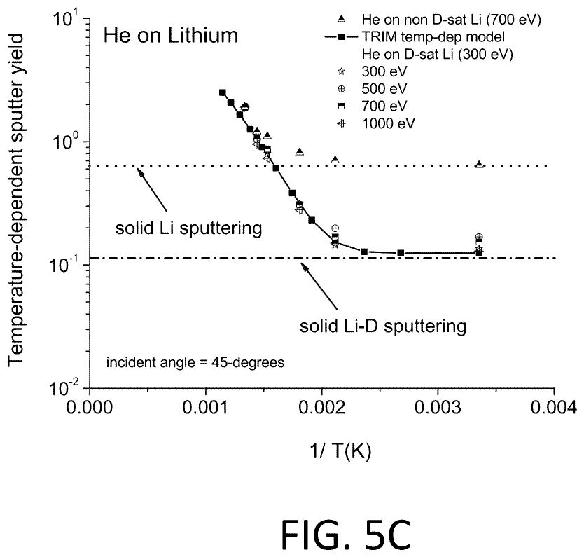

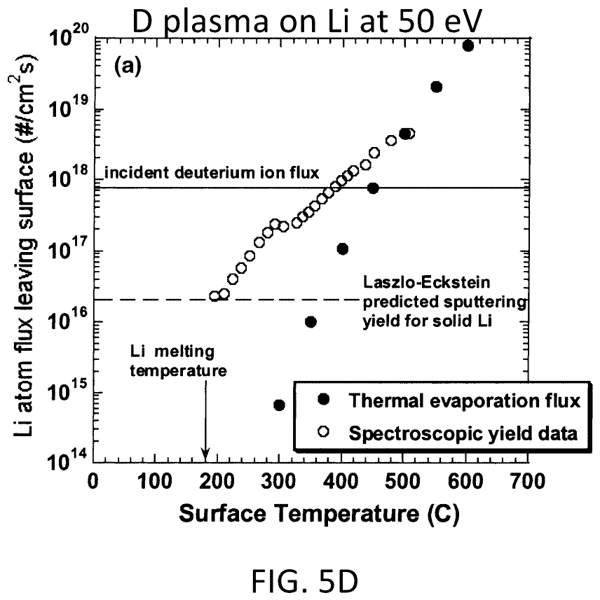

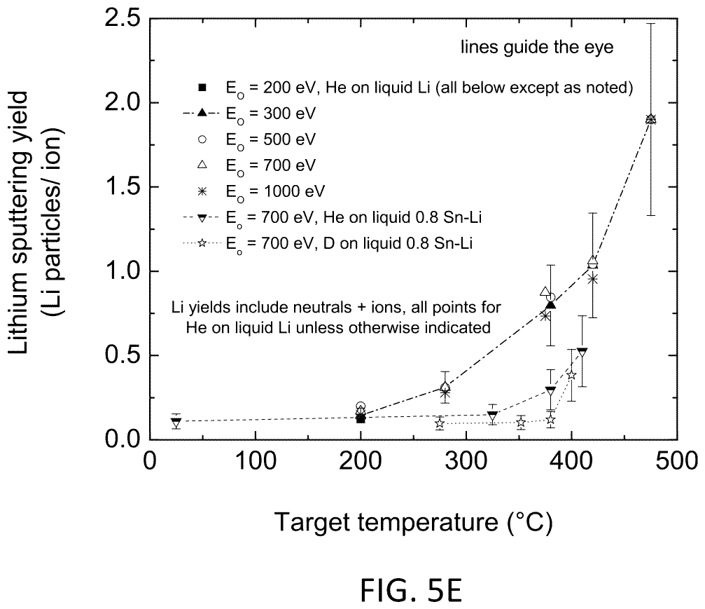

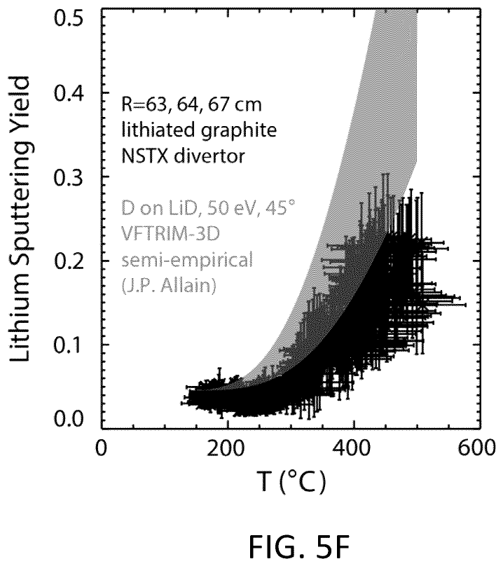

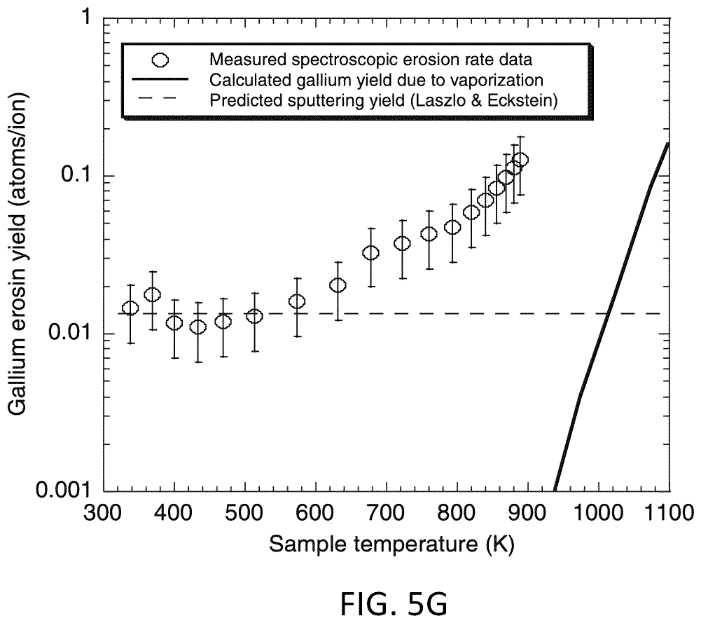

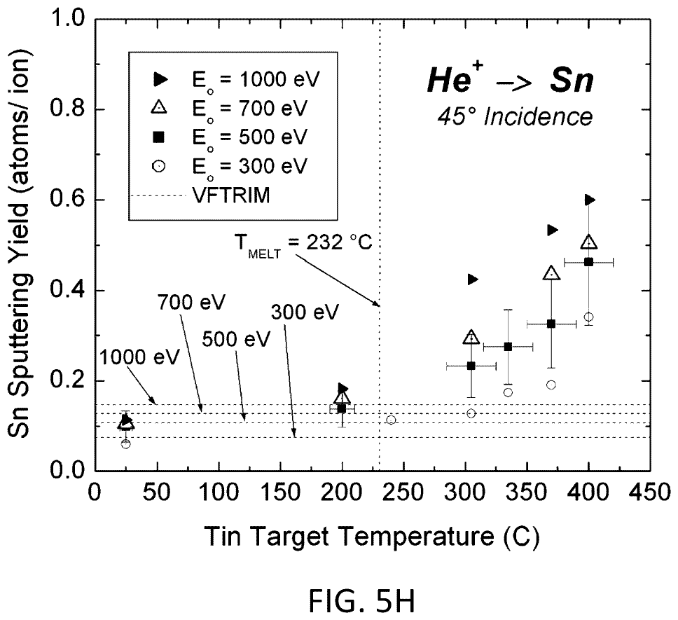

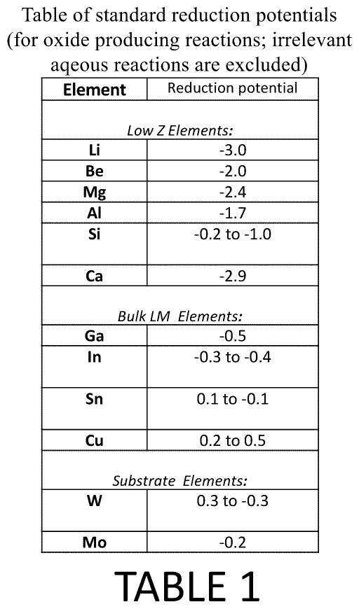

The sputtering properties of four LMs have been investigated experimentally: lithium (Li), tin (Sn), gallium (Ga) and an alloy of tin and lithium SnLi. For all four liquid metals, sputtering rapidly and strongly increases starting at a temperature of ˜400-500 C. Specifically, the sputtering yield (atoms ejected per atom impinging) increases and accelerates with increasing T. See representative experimental results in FIG. 5a-5g.

FIGS. 5a and 5b show sputtering from Li, for various projectiles. They all show temperature dependent sputtering. FIG. 5c shows that the sputtering follows an Arhennius relation. This is a temperature dependence upon T proportional to exp(−E/KT), for some E, and k is Boltzmann's constant. This type of relation is followed in an extremely diverse variety of physical-chemical phenomena, including evaporation, solubility, chemical reaction rates, etc. This behavior is obvious as a line when plotting on a log scale vs 1/T, as in FIG. 5c. FIG. 5d shows that temperature dependent sputtering arises in actual plasma exposure, as expected, and the rate of emission of target atoms can often exceed evaporation. FIG. 5e shows that temperature dependent sputtering also occurs in the alloy SnLi, and the onset temperature is only slightly higher than for pure Li. FIG. 5f shows that such sputtering appears in compounds of lithium with carbon as well and is similar to the case of pure lithium or projections for lithium hydride. FIG. 5g and FIG. 5h show that the phenomenon arises for Ga and Sn, respectively.

Let us contrast these results from the sputtering phenomenon in solids. Most solids have a weak dependence of sputtering with temperature. Such “classical” sputtering is well understood. It has a weak dependence on the temperature of the material since it is a highly non-thermal process involving energy transfers from the projectile atom that are well above thermal energies.

In a few materials, a temperature dependent kind of sputtering is known in solids, called “Radiation Enhanced Sublimation” (RES). Carbon is a material where this phenomenon is strong (unlike most solids). RES is fairly well understood as arising from crystal defect dynamics; this obviously does not pertain to liquids without any crystal structure. Various concepts have been proposed to explain temperature dependent sputtering, but none have either a consensus or any predictive capability.

So empirically, temperature dependent sputtering is primarily a phenomenon of liquids, at least, liquid metals.

Although evaporation also follows an Arrhenius relation (with smaller E in the exponential), the temperature-dependent sputtering phenomenon requires a source of high energy particles—so it is quite different.

The increased sputtering applies for all the high energy impinging particle tested, e.g., D, H, He and Li.

It is remarkable that the temperature threshold for very rapid increases in the sputtering yield is roughly the same for all four materials: ˜400-500 C. This is especially remarkable in view of the huge range in evaporation rates of these materials, and the huge range of their other properties as well.

But as we will now show, the data shows certain patterns that guide a path forward to devising LM alloys that will not show temperature dependent sputtering. The author is the first to realize these patterns, to his knowledge.

The temperature at which strong temperature dependent sputtering in FIGS. 5a-5g appears to correlate with one property all the materials have in common: they all have a low melting point that is only modestly below the onset of strong temperature where sputtering, by about 100-300 C.

Recall that large increase in sputtering with temperature is not observed for the vast majority of solid materials at all temperatures, including much higher than 400-500 C. And below their melting temperature, all these LMs also do not show strong temperature dependent sputtering, even though they show it when temperature is sufficiently above the melting point.

So being in the liquid state is a requirement for temperature dependent sputtering. But this is not sufficient. It is further necessary to have a temperature slightly above the melting point of the element.

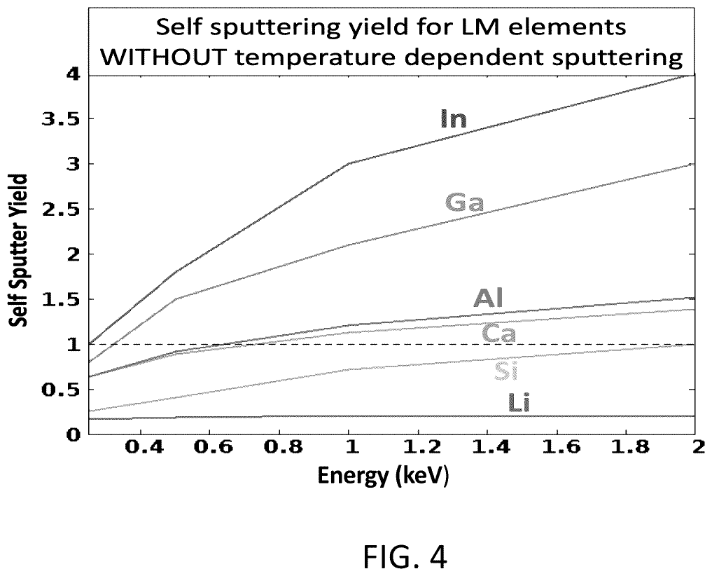

The sputtering of liquids in FIG. 4 at temperatures slightly above the melting point is similar to solid values, for all of the materials in FIG. 4. The same statement applies to other alloys considered outside of fusion [Hubbard 1989, Deoli 2014]: the sputtering was measured to be close to the values for a solid, for temperatures that did not exceed the melting point of the element on the surface by over 100-300 C.

So, the consistent pattern in the data is that temperature dependent sputtering requires that one must exceed the melting point by some amount, which is in the range of ˜100-300 degrees C., based upon the data in FIGS. 5a-5g.

We consider the data for temperature dependent sputtering a bit further to help identify a solution to the problem; we now examine how sputtering may be affected when the material is in an alloy or in a compound.

For a surface segregated material, being in an alloy apparently reduces the sputtering yield somewhat from the pure material. The reduction is often modest, less than a factor of 2. But nonetheless, there is NO significant increase because of being in a compound. See FIGS. 5a-5g. This pattern applies to SnLi ([Allain 2007]—the source of FIG. 5e) as well as to alloys outside the fusion context. (E.g., GaIn in Hubbard 1989)] and GaBi in [Deoli 2014).) It also applies to lithiated graphite (FIG. 5f), a compound-like combination of lithium and carbon [Scotti 2014].

The reduced sputtering by alloying or compounding is also shown by the fact that the temperature dependent sputtering in SnLi is delayed somewhat from the pure metal Li, and possibly also for lithiated graphite.

Chemically, alloys can be considered a chemical compound between the constituents. The compounds usually have stronger binding than the elements individually; for example, significant heat is released upon mixing of the elements for most alloys, indicating the compound is a lower (free) energy state. It is quite plausible that stronger binding should make it more difficult to eject atoms from the surface, in comparison to the elements individually.

So being in the form of an alloy or compound reduces sputtering of an element, it does not increase it.

Hence, if the element on the surface of an alloy is at a temperature less than its own melting temperature, it should not manifest strong temperature dependent sputtering, even though it is in liquid form when in an alloy.

The previous considerations taken together lead to the following practical strategy for a LM PFC: segregate an element to the surface, where that element is 100-300 C below the melting point of the that pure element, but not of the melting point of the alloy as a whole.

So, we can formulate new alloys as follows. We can start with the conventional LMs with low melting point and low vapor pressure: Ga, Sn and In, and perhaps other metals as well (such as Cu or Al to improve thermal conductivity).

In addition, alloys of Pb are sometimes considered for blankets around the core plasma. It may be convenient to use a similar alloy as in the blanket for the PFC, to simplify handling the LMs in a plant. As with the metals Ga, Sn and In, low Z non-metals segregate to the surface of Pb alloys, and further such non-metals bind more strongly to the low Z metals Li, Be, Mg, Al, Si or Ca, Sc, Ti, V, Cr, and Mn. Hence, the non-metal should draw the low Z metal to the surface.

We add to such metals as Ga, Sn, In and Pb, a low Z metallic element with a much higher melting point. Examples include some proportion of Be, Mg, Al, Si or Ca. We choose a concentration of the low Z element or elements so that the vapor pressure is low enough. We then add a low concentration of a surface-active element such as O, N, F, C, P, S, Cl, H, or B. This will segregate the low Z metallic element to the surface, because it is energetically favored to do so. Different combinations of the surface active agents can also be used, as well as only one.

The resulting segregated metal should not manifest strong temperature-dependent sputtering, since it is below the melting temperature of the pure element.

This is not the only means by which it might be possible to avoid temperature dependent sputtering. The addition of the surface-active agents described above can also lead to LM PFCs that avoid temperature dependent sputtering by a different route:

It is known that large temperature dependent sputtering does not happen to solid compounds such as oxides, nitrides, or other compounds, at least, not until the temperature is in vicinity of their melting point. Such compounds usually segregate to the surface of an alloy. Hence, even without introducing a metallic element in an alloy, one may be able to eliminate temperature dependent sputtering by adding a suitable surface-active agent as indicated below:

Choose a non-metallic surface-active agent such as O, N, F, C, P, S, H, B, and possibly others. This element can tend to form compounds with a metallic element of the liquid. For example, that compound could be an oxide, nitride, fluoride, carbide, phosphide, sulfide, chloride, hydride, or possibly others. The compounds, when they are not on the surface of an LM, are solids at the operating temperature of the alloy. The resulting LM with the surface-active agent may prevent temperature dependent sputtering.

We have also mentioned that corrosion and wetting are also properties that could be improved to lead to a better LM PFC. We discuss these now.

Consider corrosion. The low Z metals Li, Be, Mg, Al, Si, and Ca all are stronger reducing agents than bulk LM elements Ga, In, Sn, Cu, and Pb, and also, stronger reducing agents than the substrates Mo or W. See table 1. Hence, their addition to the LM tends to make the LM a more reducing medium, and for many chemical reactions, this will tend to make it less chemically corrosive to the substrate. The non-metallic elements in these alloys (O, F, N, C, S, P, H, or B) will tend to bind to those added metallic elements in the LM rather than to the substrate. This should impede or eliminate the build-up of oxide of other films on the substrate, which is part of the corrosion process. For this to be true, however, the non-metal concentration (for example, O, F, N, C, S, P, H, or B) should be considerably lower than the concentration on the low Z metal concentration (for example Li, Be, Mg, Al, Si and Ca, Sc, Ti, V, Cr, or Mn). Fortunately, the concentrations of the non-metals necessary to lead to surface coverage are often quite small. For example, for O, it is often in the range of 106 to 104. Compared to these non-metals, the fractions of the elements Li, Be, Mg, Al, Si, and Ca are in the percent range, that is, orders of magnitude higher. Thus, the overall addition of metallic elements and non-metallic elements can achieve segregation while still being a net reducing addition to the LM. A general rule of thumb is that alloying additives that are a net reducing agent will tend to protect the substrate from attack by the non-metals.

The highly reducing metallic additions to the LM should also reduce the formation of oxides on the substrate that impede wetting.

Regarding wetting, as just mentioned, the LM additions contemplated here can reduce the formation of oxides and other corrosion compound coatings on the substrate. These generally degrade wetting of LM, and this in itself should improve wetting. And as noted before, LM wetting almost always improves with higher temperature. Since these LM can operate at higher temperature, for all the reasons stated above, this should also improve wetting.

We now turn to the subject of how the segregation can be maintained over time. The surface-active agent will be sputtered, and so will be depleted in the alloy over time. Such material will have to be replenished. There are many possible ways to do this, and here we state several examples, but there are others. To replenish the surface-active agent, we could choose a gaseous material containing the element (such as the pure element or a compound containing it), or have that element be a component of the plasma impinging upon the PFC, and have a pressure of that element in the PFC region high enough so that of the surface-active gas will replace material lost to sputtering. Alternatively, the gas could be applied to the liquid at surfaces other than the PFC location, and then that LM could be transported to the PFC location. Another possible means to replenish the material is to recirculate the LM, and have a new alloy with a high level of surface-active agent replenish it. This can be accomplished in various ways. To replenish the surface-active agent in the LM, it could be introduced in various forms, including, but not limited to, a solid, liquid, gas, or compound of the surface agent with other elements.

The low Z metallic element, which is also sputtered away, could be replenished by similar means to the ones listed above for the surface-active agent.

Other means could be devised to replace sputtered material from the LM as well, the methods above are just some examples.

Finally, let us consider specific examples of alloys for LM PFCs, and their advantages.

Alloys with Li: The advantage of Li is that it has the lowest Z of any metal, and thus should lead to the least impact upon the plasma per atom. The drawback is the high vapor pressure of Li and the low temperature where temperature dependent sputtering sets in. The alloy SnLi has been investigated as a PFC where the fraction of Li is typically 20-30 atomic percent. Other alloys have been mentioned (GaLi and InLi) but not examined in detail. Although the vapor pressure of SnLi is three orders of magnitude less than Li, it is still several orders of magnitude higher than pure Sn. By reducing the concentration of Li to on the order of percents or less, the vapor pressure of SnLi could be reduced by a further 1-2 orders of magnitude, and it would approach that of pure Sn. However, the segregation mechanism would have to be strong to concentrate Li on the surface so that Li dominates the sputtering. As mentioned before, for LM alloys outside of the plasma context, such extreme levels of segregation have been measured: for GaBi, even 0.2% Bi in the bulk nonetheless resulted in ˜80% of the sputtered material being measured. For this example, the segregation was attributable to the extreme surface tension differences between Ga and Bi. This does not occur for the alloys SnLi, GaLi, InLi or PbLi. But the energetic strength of the chemical segregation mechanism described here can be estimated to be this strong or stronger. Hence, with a surface-active agent like some proportions of O, F, N, S, P or possibly C, H, or B, it should be possible to have alloys with low concentrations of Li with some proportion of Sn, Ga and In (and thus very low vapor pressure) but also segregation of the Li to the surface so that it dominates sputtering. Although the vapor pressure of Pb in not as low as Sn, Ga and In, it is nonetheless lower.

The issue of temperature dependent sputtering is still important. However, if the segregated Li is in the form of a compound like LizO or LiF, then temperature dependent sputtering might be avoided.

Hence, alloys of Li with the Sn, Ga, In, and possibly other metals including Pb, together with a surface segregant, can have higher operating temperature and thus be advantageous PFCs while still presenting a low Z surface to the plasma. The operating temperature could be high enough so that in addition to Sn, Ga and In, one can add Cu or Al to the alloy to improve its thermal conductivity.

Alloys with Be: The advantage of Be is that it is very low Z, almost as low as Li, so it also has exceptionally low impact upon the plasma per atom. Beryllium also has very low vapor pressure and high melting point so it has very low evaporation and should avoid temperature-dependent sputtering. The drawback is that Be has very low solubility in most liquid metals, including Sn, Ga and In [Elliot 1955]. At typical temperatures for a PFC, the solubility is of order 1% or less. So, without the strong chemical segregation mechanism described in this patent, it would not dominate the sputtering in an LM PFC alloy. The energetic strength of the chemical segregation should be strong enough to enable segregation of Be to the surface. Hence, with a surface-active agent it should be possible to have alloys with some proportion of Sn, Ga and In where the Be segregates to the surface and dominates sputtering. Possible surface-active agents with low Z include O, F, N, S, P, C, H, or B. The vapor pressure of Be is low enough so that it can operate at very high temperature, so that in addition to some proportion of Sn, Ga and In, one can add Cu or Al to the alloy to improve its thermal conductivity.

Alloys with Mg: The advantage of Mg is that it has fairly low Z. Another advantage is that it has good compatibility with many substrates. However, it has high vapor pressure and relatively low melting point, so that both evaporation and temperature dependent sputtering are issues for a PFC. The issue of vapor pressure can be addressed by having the atomic fraction in the alloy be of order 1% or less. At such low concentrations, without the strong chemical segregation mechanism described in this patent, it would not dominate the sputtering. The energetic strength of the chemical segregation should be strong enough to enable segregation it to the surface. Hence, with a surface-active agent it should be possible to have alloys with some proportion of Sn, Ga and In where the Mg segregates to the surface and dominates sputtering. Possible surface-active agents with low Z include O, F, N, S, P, C, H, or B. So, together with a surface-active agent, alloys of Mg with some proportion of Sn, Ga and In could operate at high temperatures, thus it is possible to add Cu or Al to the alloy to improve its thermal conductivity. In the event that the surface heat flux became too high, Mg evaporation would become significant (Mg has a Z similar to Ne, which is widely considered to increase divertor radiation). This would produce radiation in the SOL that would reduce the heat flux. So, such a PFC would be self-protecting as well.

Alloys with Al: The advantage of Al is that it has fairly low Z and low vapor pressure. Its high melting point is high enough that it might avoid temperature dependent sputtering for a significant temperature range. A drawback is that pure Al has extremely poor compatibility with metal substrates. However, a concentration of Al in the alloy should greatly ameliorate this. The energetic strength of the chemical segregation should, in fact, be strong enough to enable segregation of it to the surface even for low concentrations. Hence, with a surface-active agent it should be possible to have alloys with some proportion of Sn, Ga and In where the Al segregates to the surface and dominates sputtering. Possible surface-active agents with low Z include O, F, N, S, P, C, H, or B. The vapor pressure of Al is low enough so that it can operate at high temperature, so one can add Cu to the alloy to improve its thermal conductivity.

Alloys with Si: The advantage of Si is that it has fairly low Z, and experiments have found it has good compatibility with the core plasma, sometimes even improving confinement. Silicon has extremely low vapor pressure and very high melting point so it has very little evaporation and should avoid temperature dependent sputtering. The drawback is that Si has very low solubility in most liquid metals in the relevant temperature range, including Sn, Ga, and In. At typical temperature, the solubility is of order 1% or less, so without the strong chemical segregation mechanism described in this patent, it would not dominate the sputtering. The energetic strength of the chemical segregation should, in fact, be strong enough to enable segregation of it to the surface. Hence, with a surface-active agent it should be possible to have alloys with some proportion of Sn, Ga and In where the Si segregates to the surface and dominates sputtering. Possible surface-active agents with low Z include O, F, N, S, P, C, H, or B. The vapor pressure of Si is low enough so that it can operate at very high temperatures, so, one can add Cu or Al to the alloy to improve its thermal conductivity.

Alloys with Ca: The advantage of Ca is that it has moderately low Z, though not as low as the other elements above. Nonetheless, it should be acceptable. Its impact on the plasma is similar to Argon, and some levels of Ar impurity are regarded as acceptable in fusion plasmas. The melting temperature is high, so it should avoid temperature dependent sputtering. The drawback is the relatively high vapor pressure of Ca. By reducing the concentration of Ca to of order of low percents or less, the vapor pressure could be reduced so that the alloy operates at high temperature. However, at such low concentrations, the segregation mechanism would have to be strong. The energetic strength of the chemical segregation mechanism described here can be estimated to be strong enough for this. Hence, with a surface-active agent, it should be possible to have alloys (with low concentrations of Ca and thus low vapor pressure) with some proportion of Sn, Ga and In where the Ca segregates to the surface and dominates sputtering. Possible surface-active agents with low Z include O, F, N, S, P, C, H or B. Hence, alloys of Ca with the Sn, Ga, In, can have higher operating temperature, high enough so that one can add Cu or Al to the alloy to improve its thermal conductivity. In the event that the surface heat flux became too high, Ca evaporation would become significant, and this would cause substantial divertor radiation. Calcium has a Z similar to Ar, which is widely considered in the art to increase divertor radiation. This would produce radiation in the SOL that would reduce the heat flux. So, such a PFC would be self-protecting as well.

Higher Z elements can also be considered as well, but they have higher impact upon the plasma. Nonetheless, they might provide advantageous alloys in some circumstances.

Alloys with Sc, Ti, V, Cr or Mn: The advantage of these elements is that they have very low vapor pressure and very high melting points, so their evaporation is low and they avoid temperature-dependent sputtering. The drawback is that these elements have very low solubility in most liquid metals in the relevant temperature range, including Sn, Ga, and In. At typical temperature, the solubility is of order 1% or less. An advantage is the energetic chemical strength of the chemical segregation should, in fact, be strong enough to enable segregation of these to the surface. Hence, with a surface-active agent it should be possible to have alloys where these dominate sputtering. Possible agents with low Z include O, F, N, S, P, C, H, or B. The vapor pressure of these should be low enough so that it can operate at very high temperature, so that one can add Cu or Al to the alloy to improve its thermal conductivity.

Of course, it is also possible to add more than one metal among the group Li, Be, Mg, Al, Si and Ca, Sc, Ti, V, Cr and Mn to a PFC. Such combinations could combine the advantages above.

Also, it is possible to consider alloys of only the low Z metals Li, Be, Mg, Al, Si and Ca. Pure lithium has long been considered as a PFC, but adding other elements to create alloys where the atomic Li content is less than 98% would have advantages that have never been considered in the art. An example is CaLi, which should be a low recycling material like lithium, since Ca binds strongly to H. Its vapor pressure would be somewhat lower than pure Li, so it can operate at higher temperature. Its melting point can be less than pure Li, which is another advantage. Another advantage is that Ca has better wetting of many substrates, compared to Li. Furthermore, by segregating a low Z element to the surface other than Li, temperature dependent sputtering can be prevented over a considerable temperature range. This could be accomplished with surface active agents. Possible agents with low Z include O, F, N, S, P, C, H, or B.

Finally, while the present invention has been described above with reference to various exemplary embodiments, many changes, combinations and modifications may be made to the exemplary embodiments without departing from the scope of the present invention. For example, the various components may be implemented in alternative ways. These alternatives can be suitably selected depending upon the particular application or in consideration of any number of factors associated with the operation of the device. In addition, the techniques described herein may be extended or modified for use with other types of devices. These and other changes or modifications are intended to be included within the scope of the present invention.

REFERENCES: Each of the references listed below is incorporated herein in its entirety by reference.

### Allain 2001

“Kinematic and Thermodynamic Effects on Liquid Lithium Sputtering”, J. P. Allain, Ph.D. thesis, University of Illinois at Urbana-Champaign, 2001

### Allain 2005

“A model for ion-bombardment induced erosion enhancement with target temperature in liquid lithium” J. P. Allain et. al., Nucl Instrum Methods Phys Res B Vol 239, Issue 4, pg 247 (2005).

### Allain 2007

“Collisional and thermal effects on liquid lithium sputtering”, J. P. Allain, M. D. Coventry, and D. N. Ruzic, Phys. Rev. B 76, 205434 2007

### Anson 1999

“The surface tension of molten aluminum and Al—Si—Mg alloy under vacuum and hydrogen atmospheres”, Anson, J. P., Drew, R. A. L. & Gruzleski, J. E. Metall Mater Trans B 30, 1027-1032 (1999)

### Bastasz 2004

“Surface composition of liquid metals and alloys”

R. Bastasz, J. A. Whaley, Fusion Engineering and Design 72 (2004) 111-119

### Bataglia 2020

“Enhanced pedestal H-mode at low edge ion

collisionality on NSTX”, D. J. Battaglia et. al., Phys. Plasmas 27, 072511 (2020)

Castro 2021 “Lithium, a path to make fusion energy affordable”, A. de Castro, Phys. Plasmas 28, 050901 (2021)

### Conn 2002

“Deuterium plasma interactions with liquid gallium” R. W. Conn et al 2002 Nucl. Fusion 42

### Coventry 2004

“Temperature dependence of liquid Sn sputtering by low-energy He and D bombardment”, M. D. Coventry et al Journal of Nuclear Materials 335 (2004) 115-120

### Dejarnac 2020

“Overview of power exhaust experiments in the COMPASS divertor with liquid metals”, R. Dejarnac et. al., Nucl. Mater. Energy 25 (2020) 10080

Doerner 2001 “Measurements of erosion mechanisms from solid and liquid materials in PISCES-B”, R. P. Doerner et. al., Journal of Nuclear Materials 290-293 (2001) 166

### Deoli 2014

“Sputtering of Bi and preferential sputtering of an inhomogeneous alloy”, Naresh T. Deoli, Doctorate Dissertation at University of North Dallas 2014

### Elliot 1955

“The solubility of beryllium in liquid gallium, tin and indium, and the phase diagrams of beryllium with these metals”, Elliott, R. O., Los Alamos Scientific Laboratory, U.S. Atomic Energy Commission. (1952) Oak Ridge, Tennessee: Technical Information Service

### FIORI 2005

“Dynamic surface tension measurements on a molten metal-oxygen system: The behaviour of the temperature coefficient of the surface tension of molten tin”, L. FIORI, E. RICCI*, E. ARATO‡, P. COSTA, JOURNAL OF MATERIALS SCIENCE 40 (2005) 2155-2159

### Gheribi 2019

“Temperature and oxygen adsorption coupling effects upon the surface tension of liquid metals”, Gheribi, A. E., Chartrand, P., Sci Rep 9, 7113 (2019). https://doi.org/10.1038/s41598-019-43500-3

### Goldston 2017

“Recent advances towards a lithium vapor box divertor”, R. J. Goldston et al. Nuclear Materials and Energy 12 (2017) 1118-1121

### Hodes 2014

M. Hodes, R. Zhang, L. S. Lam, R. Wilcoxon and N. Lower, “On the Potential of Galinstan-Based Minichannel and Minigap Cooling,” in IEEE Transactions on Components, Packaging and Manufacturing Technology, vol. 4, no. 1, pp. 46-56, January 2014, doi: 10.1109/TCPMT.2013.2274699

### Hubbard 1989

“Sputtering from a liquid Ga—In eutectic alloy”, K. M. Hubbard et al, Nucl. Instrum. Methods Phys Res B, Vol 40-41, Part 1, 2 Apri 1989, pg 278

### Huber 2019

“Determination of tungsten sources in the JET-ILW divertor by spectroscopic imaging in the presence of a strong plasma continuum”, A. Huber et. al., Nuclear Materials and Energy 18 (2019) 118-124

### IAEA-FLYCHK

www-amdis.iaea.org/FLYCHK/Joud

### Joud 1995

“An auger investigation of oxygen-enhanced tin segregation on a liquid Pb—Sn alloy”, Joud, J. C., Ricci, E. & Passerone, A. Il Nuovo Cimento D 17, 365-380 (1995)

### Katoh 2019

“Response of unalloyed tungsten to mixed spectrum neutrons” Y. Katoh et. al., Journal of Nuclear Materials 520 (2019) 193-207

### Kessel 2019

“Critical Exploration of Liquid Metal Plasma-Facing Components in a Fusion Nuclear Science Facility”, C. E. Kessel et. al., Fuison Science and Technology 75, 886 (2019)

### Khodak 2022

“Plasma facing components with capillary porous system and liquid metal coolant flow”, A. Khodak and R. Maingi, Phys. Plasmas 29, 072505 (2022)

### Kotschenreuther 2019

“GYROKINETIC ANALYSIS AND SIMULATION OF PEDESTALS TO IDENTIFY THE CULPRITS FOR ENERGY LOSSES USING ‘FINGERPRINTS’”, M. KOTSCHENREUTHER ET. AL., 2019 NUCL. FUSION 59 096001

### Kotschenreuther 2023

“Transport Barriers in Magnetized Plasmas—General Theory with Dynamical Constraints” M. Kotschenreuther, X. Liu, S. Mahajan, D. R. Hatch, G. Merlot ArXiv arXiv:2310.17107

### Krasin 2019

“Important Thermodynamic Parameters of Lithium-Tin Alloys from the Point of View of Their Use in Tokamaks, V. P. Krasin and S. I. Soyustova, High Temperature, 2019, Vol. 57, No. 2, pp. 190-197.

### Lomanowski 2022

“Experimental study on the role of the target electron temperature as a key parameter linking recycling to plasma performance in JET-ILW”, B. Lomanowski et al 2022 Nucl. Fusion 62 066030″

### Mazzitelli 2019

“Experiments on the Frascati Tokamak Upgrade with a liquid tin limiter”, G. Mazzitelli et. al., Nucl. Fusion 59 (2019) 096004

### Majeski 2010

“Liquid Metal Walls, Lithium, And Low Recycling Boundary Conditions In Tokamaks”, R. Majeski AIP Conference Proceedings 1237, 122 (2010)

### Menard 2022

“Fusion Pilot Plant performance and the role of a Sustained High Power Density tokamak” J. E. Menard et al 2022 Nucl. Fusion 62 036026

### Nallo 2022

“SOLPS-ITER simulations of a CPS-based liquid metal divertor for the EU DEMO: Li vs. Sn”, G. F. Nallo et. al., Nucl. Fusion 62 036008 (2022)

### PASSERONE 1990

“Influence of oxygen contamination on the surface tension of liquid tin”, A. PASSERONE, E. RICCI, R. SANGIORGI, JOURNAL OF MATERIALS SCIENCE 25 (1990) 4266-4272

### Regan 1997

“X-ray study of the oxidation of liquid-gallium surfaces’ M. J. Regan et. al., PHYSICAL REVIEW B VOLUME 55, NUMBER 16 15 Apr. 1997-II

### Rindt 2021

“Conceptual design of a liquid-metal divertor for the European DEMO”, P. Rindt et. al., Fusion Engineering and Design 173 (2021) 112812

### Roccella 2020

“CPS Based Liquid Metal Divertor Target for EU-DEMO”,

S. Roccella et. al., Journal of Fusion Energy (2020) 39:462-468

### Ruzic 2011

“Lithium-metal infused trenches (LiMIT) for heat removal in fusion devices”, D. N. Ruzic et al 2011 Nucl. Fusion 51 102002

### Scholte 2023

“Performance of a liquid Sn divertor target during ASDEX upgrade L-mode and H-mode operation”, J. Scholte et. al., Nucl. Mater. Energy 37 (2023) 101522

### [Scotti 2014]

“Lithium sputtering from lithium-coated plasma facing component in the NSTX divertor”, F. Scotti et al, Journal of Nuclear Materials 463 (2015) 1165

### Shoji 2015

“Studies of dust transport in long pulse plasma discharges in the large helical device”, M. Shoji et al 2015 Nucl. Fusion 55 053014

### Stangeby 2011

“Obtaining reactor-relevant divertor conditions in tokamaks”, P. C. Stangeby Nucl. Fusion 51 (2011) 063001

### Strachan 1994

“Studies of global energy confinement in TFTR supershots”, J. D. Strachan 1994 Nucl. Fusion 34 1017

### Tabares 2017

“Experimental tests of LiSn alloys as potential liquid metal for the divertor target in a fusion reactor”, F. L. Tabarés et. al., Nucl. Mater. Energy, 12 (2017) 1368-1373

### Underwood 2021

“Dual Coolant Liquid Metal Divertor Development”, DOE SBIR grant abstract, https://www.osti.gov/biblio/1818199

### Verdoolaege 2021

“The updated ITPA global H-mode confinement database: description and analysis”, G. Verdoolaege 2021 Nucl. Fusion 61 076006

### Zakharov 2019

“On a burning plasma low recycling regime with PDT=23-26 MW, QDT=5-7 in a JET-like tokamak”, L. E. Zakharov Nucl. Fusion 59 (2019) 096008

### Zhang 2013

R. Zhang, M. Hodes, N. Lower and R. Wilcoxon, “Thermo-fluid characteristics of a minichannel heat sink cooled with liquid metal,” 29th IEEE Semiconductor Thermal Measurement and Management Symposium, 2013, pp. 159-165, doi: 10.1109/SEMI-THERM.2013.6526822

### Zhang 2015

“Water-Based Microchannel and Galinstan-Based Minichannel Cooling Beyond 1 kW/cm2 Heat Flux”, IEEE TRANSACTIONS ON COMPONENTS, PACKAGING AND MANUFACTURING TECHNOLOGY, Vol. 5, No. 6, June 2015

What is claimed is:

1. A surface exposed to a plasma or energetic particles (“plasma-exposed surface”) in a device to confine a plasma, the surface comprising:
a liquid composition wherein metallic elements dominate by atomic fraction and wherein elements with Z<26 are not primarily lithium by atomic fraction.

2. The plasma-exposed surface of claim 1, wherein over 95% of the elements with atomic number Z<26 are selected from the group of elements comprising: Li, Be, Mg, Al, Si, Ca, O, N, F, C, P, S, Cl, H, and B.

3. The plasma-exposed surface of claim 2, wherein some of the elements in the liquid composition with Z<26 have a higher concentration on the surface of the material than in the volume of the material.

4. The plasma-exposed surface of claim 3, where the elements with Z>26 are predominantly comprised of any proportion of Ga, Sn, In, Cu and Pb.

5. The plasma-exposed surface of claim 3, where some elements with Z<26 are from the group of metallic and semi-metallic elements Li, Be, Mg, Al, Si, Ca, Sc, Ti, V, Cr and Mn and in addition there are some elements from the non-metallic group of O, N, F, C, P, S, Cl, B and H, and the summed atomic fraction of all the non-metallic elements O, N, F, C, P, S, Cl, B is less than the summed atomic fraction of all the metallic and semi-metallic elements Li, Be, Mg, Al, Si, Ca, Sc, Ti, V, Cr and Mn.

6. The plasma-exposed surface of claim 4, where some elements in the liquid composition with Z<26 are from the group of metallic and semi-metallic elements comprising Li, Be, Mg, Al, Si, and Ca.

7. The plasma-exposed surface of claim 1, where the metallic element in the liquid composition with atomic number Z<26 is predominantly Be, and where non-metallic elements are present from among the group comprising N, O, F, P, S, Cl, C, H and B.

8. The plasma-exposed surface of claim 7, where metallic elements in the liquid composition are primarily comprised of any proportion of Ga, In, Sn, Cu, Al and Pb and wherein the summed atomic fraction of all the metallic and semi-metallic elements with Z<26 is greater than the sum of the atomic fraction of non-metallic elements with Z<26.

9. The plasma-exposed surface of claim 1, where the metallic element in the liquid composition with atomic number Z<26 is predominantly Mg, and where non-metallic elements are present from among the group comprising N, O, F, P, S, Cl, C, H and B.

10. The plasma-exposed surface of claim 9, where the metallic elements in the liquid composition are primarily comprised of any proportion of Ga, In, Sn, Cu, Al and Pb and wherein the summed atomic fraction of all the metallic and semi-metallic elements with Z<26 is greater than the sum of the atomic fraction of non-metallic elements with Z<26.

11. The plasma-exposed surface of claim 1, where the metallic element with atomic number Z<26 is predominantly Al, and where non-metallic elements are present from among the group comprising N, O, F, P, S, Cl, C, H and B.

12. The plasma-exposed surface of claim 11, where the metallic elements in the liquid composition are primarily comprised of any proportion of Ga, In, Sn, Cu and Pb and wherein the summed atomic fraction of all the metallic and semi-metallic elements with Z<26 is greater than the sum of the atomic fraction of non-metallic elements with Z<26.

13. The plasma-exposed surface of claim 1, where the metallic element in the liquid composition with atomic number Z<26 is predominantly Si, and where non-metallic elements are present from among the group comprising N, O, F, P, S, Cl, C, H and B.

14. The plasma-exposed surface of claim 13, where the metallic elements in the liquid composition are primarily comprised of any proportion of Ga, In, Sn, Cu, Al and Pb and where the summed atomic fraction of all the metallic and semi-metallic elements with Z<26 is greater than the sum of the atomic fraction of non-metallic elements with Z<26.

15. The plasma-exposed surface of claim 1, where the metallic element in the liquid composition with atomic number Z<26 is predominantly Ca, and where non-metallic elements are present from among the group comprising N, O, F, P, S, Cl, C, H and B.

16. The plasma-exposed surface of claim 15, where the metallic elements in the liquid composition are primarily comprised of any proportion of Ga, In, Sn, Cu, Al and Pb and where the summed atomic fraction of all the metallic and semi-metallic elements with Z<26 is greater than the sum of the atomic fraction of non-metallic elements with Z<26.

17. The plasma-exposed surface of claim 1, where the metallic element in the liquid composition with atomic number Z<26 is primarily any proportion of Sc, Ti, V, Cr and Mn, and where non-metallic elements are present from among the group comprising N, O, F, P, S, Cl, C, H and B.

18. The plasma-exposed surface of claim 17, where the metallic elements in the liquid composition are primarily comprised of any proportion of Ga, In, Sn, Cu, Al and Pb and where the summed atomic fraction of all the metallic and semi-metallic elements with Z<26 is greater than the sum of the atomic fraction of non-metallic elements with Z<26.

19. A surface exposed to a plasma or energetic particles in a device to confine a plasma, the surface comprising:
a liquid composition wherein metallic elements dominate by atomic fraction and wherein elements with Z<26 are primarily lithium by atomic fraction,
and Li is present at an atomic concentration of less that 98%
and where non-metallic elements are present from among the group comprising N, O, F, P, S, Cl, C, H and B.

20. The plasma-exposed surface of claim 19, where Li is present at an atomic concentration of less than 90%
